(19) United States
(12) Patent Application Publication
(10) Pub. No.: US 2025/0220900 A1
(43) Pub. Date: Jul. 3, 2025

(54) SEMICONDUCTOR DEVICE, METHOD OF MANUFACTURING THE SAME, AND ELECTRONIC SYSTEM INCLUDING THE SAME

(71) Applicant: Samsung Electronics Co., Ltd., Suwon-si (KR)

(72) Inventors: Juseong MIN, Suwon-si (KR); Jaebok BAEK, Suwon-si (KR); Taekkyu YOON, Suwon-si (KR); Jeehoon HAN, Suwon-si (KR)

(73) Assignee: Samsung Electronics Co., Ltd., Suwon-si (KR)

(21) Appl. No.: 18/978,187

(22) Filed: Dec. 12, 2024

(30) Foreign Application Priority Data
Dec. 29, 2023 (KR) 10-2023-0197639

(51) Int. Cl. H10B 41/35; G11C 16/04; H01L 25/07; H10B 41/10; H10B 41/27; H10B 41/41; H10B 43/10; H10B 43/27; H10B 43/35; H10B 43/40; H10B 80/00

(52) U.S. Cl. CPC H10B 41/35; G11C 16/0483; H01L 25/074; H10B 41/10; H10B 41/27; H10B 41/41; H10B 43/10; H10B 43/27; H10B 43/35; H10B 43/40; H10B 80/00; H01L 2225/06506

(57) ABSTRACT

A semiconductor device includes a substrate having a first active region, a second active region, and a third active region, a first transistor on the first active region and including a first gate structure, which includes a first gate insulating layer and a first gate electrode, a second transistor on the second active region and including a second gate structure, which includes a second gate insulating layer including a high dielectric layer, a work function metal layer, and a second gate electrode, and a third transistor on the third active region and including a third gate structure, which includes a third gate insulating layer including a high dielectric layer, a work function metal layer, and a third gate electrode, wherein the first gate electrode includes a first semiconductor layer and a second semiconductor layer that are sequentially arranged on the first gate insulating layer and each include polysilicon.

### CROSS-REFERENCE TO RELATED APPLICATION

This application is based on and claims priority under 35 U.S.C. § 119 to Korean Patent Application No. 10-2023-0197639, filed on Dec. 29, 2023, in the Korean Intellectual Property Office, the disclosure of which is incorporated by reference herein in its entirety.

### BACKGROUND

The inventive concepts relate to semiconductor devices, methods of manufacturing the semiconductor device, and/or electronic systems including the semiconductor device, and more particularly, to semiconductor devices having a vertical channel, methods of manufacturing the semiconductor device, and/or electronic systems including the semiconductor device.

Electronic systems, which need to store data, require semiconductor devices that can store high-capacity data. Accordingly, ways to increase the data storage capacity of semiconductor devices are being studied. For example, in order to increase the data storage capacity of a semiconductor device, a semiconductor device, which includes memory cells arranged three-dimensionally instead of memory cells arranged two-dimensionally, is proposed.

### SUMMARY

The inventive concepts provide semiconductor devices with increased operational reliability, methods of manufacturing the semiconductor device, and/or electronic systems including the semiconductor device.

According to an example embodiment of the inventive concepts, a semiconductor device includes a substrate having a first active region, a second active region, and a third active region defined by a device isolation layer, a first transistor arranged on the first active region and including a first gate structure which includes a first gate insulating layer arranged on the first active region and a first gate electrode arranged on the first gate insulating layer, a second transistor arranged on the second active region and including a second gate structure which includes a second gate insulating layer arranged on the second active region and including a high dielectric layer, a work function metal layer arranged on the second gate insulating layer, and a second gate electrode arranged on the work function metal layer and including metal, and a third transistor arranged on the third active region and including a third gate structure which includes a third gate insulating layer arranged on the third active region and including a high dielectric layer, a work function metal layer arranged on the third gate insulating layer, and a third gate electrode arranged on the work function metal layer and including metal, wherein the first gate electrode includes a first semiconductor layer and a second semiconductor layer which are sequentially arranged on the first gate insulating layer and each include polysilicon.

According to an example embodiment of the inventive concepts, a semiconductor device includes a peripheral circuit structure provided on a substrate, and a cell array structure arranged on the peripheral circuit structure and including a plurality of memory cells arranged in a vertical direction perpendicular to an upper surface of the substrate, wherein the peripheral circuit structure includes a device isolation layer arranged on the substrate and defining a first active region, a second active region, and a third active region, a first gate structure arranged on the first active region and including a first gate insulating layer and a first gate electrode arranged on the first gate insulating layer, a second gate structure arranged on the second active region and including a second gate insulating layer which includes a high dielectric layer, a work function metal layer arranged on the second gate insulating layer, and a second gate electrode arranged on the work function metal layer and including metal, a third gate structure arranged on the third active region and including a third gate insulating layer which includes a high dielectric layer, a work function metal layer arranged on the third gate insulating layer, and a third gate electrode arranged on the work function metal layer and including metal, and the first gate electrode includes a first semiconductor layer and a second semiconductor layer which are sequentially arranged on the first gate insulating layer and each include polysilicon.

According to an example embodiment of the inventive concepts, an electronic system includes a main board, a semiconductor device on the main board, and a controller electrically connected to the semiconductor device on the main board, wherein the semiconductor device includes a peripheral circuit structure provided on a substrate, and a cell array structure arranged on the peripheral circuit structure and including a plurality of memory cells arranged in a vertical direction perpendicular to an upper surface of the substrate, the peripheral circuit structure includes a device isolation layer arranged on the substrate and defining a first active region, a second active region, and a third active region, a first gate structure arranged on the first active region and including a first gate insulating layer including a silicon oxide film and a first gate electrode arranged on the first gate insulating layer, a second gate structure arranged on the second active region and including a second gate insulating layer which includes a first insulating layer including a silicon oxide film and includes a second insulating layer including a high dielectric film, a work function metal layer arranged on the second gate insulating layer, and a second gate electrode arranged on the work function metal layer and including metal, and a third gate structure arranged on the third active region and including a third gate insulating layer which includes a high dielectric layer, a work function metal layer arranged on the third gate insulating layer, and a third gate electrode arranged on the work function metal layer and including metal, the first gate electrode includes a first semiconductor layer and a second semiconductor layer which are sequentially arranged on the first gate insulating layer and each include polysilicon, and an upper surface of the first semiconductor layer is at the same vertical level as an upper surface of the first insulating layer and an upper surface of the third gate insulating layer.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram illustrating a semiconductor device according to an example embodiment;

FIG. 2 is an equivalent circuit diagram of a memory cell array of a semiconductor device, according to an example embodiment;

FIG. 3 is a perspective view schematically illustrating a semiconductor device according to an example embodiment;

FIG. 4 is a cross-sectional view illustrating a semiconductor device according to an example embodiment;

FIG. 5 is a layout diagram illustrating a peripheral circuit structure of the semiconductor device of FIG. 4;

FIG. 6 is a cross-sectional view taken along line A-A′ of FIG. 5;

FIG. 7 is an enlarged cross-sectional view of a portion EX of FIG. 4;

FIG. 8 is a cross-sectional view illustrating a semiconductor device according to an example embodiment;

FIGS. 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21, 22, 23, 24, 25, and 26 are cross-sectional views illustrating a method of manufacturing a semiconductor device, according to an example embodiment;

FIG. 27 is a diagram schematically illustrating an electronic system including a semiconductor device, according to an example embodiment;

FIG. 28 is a perspective view schematically illustrating an electronic system including a semiconductor device, according to an example embodiment; and

FIG. 29 is a cross-sectional view schematically illustrating a semiconductor package according to an example embodiment.

### DETAILED DESCRIPTION

Hereinafter, some example embodiments are described in detail with reference to the attached drawings. The same reference numerals are used for the same components in the drawings, and redundant descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

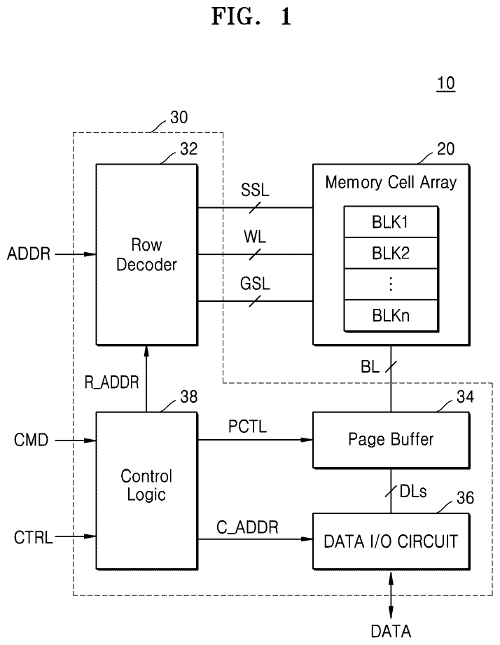

FIG. 1 is a block diagram illustrating a semiconductor device 10 according to an example embodiment.

Referring to FIG. 1, the semiconductor device 10 may include a memory cell array 20 and a peripheral circuit 30. The memory cell array 20 includes a plurality of memory cell blocks BLK1, BLK2, . . . , BLKn. Each of the plurality of memory cell blocks (BLK1, BLK2, . . . , BLKn) may include a plurality of memory cells. The plurality of memory cell blocks BLK1, BLK2, . . . , BLKn may be connected to the peripheral circuit 30 through a plurality of bit lines BL, a plurality of word lines WL, a plurality of string select lines SSL, and a ground select line GSL.

The peripheral circuit 30 may include a row decoder 32, a page buffer 34, a data input/output circuit 36, and a control logic 38. Although not illustrated in FIG. 1, the peripheral circuit 30 may further include an input/output interface, a column logic, a voltage generator, a pre-decoder, a temperature sensor, a command decoder, an address decoder, an amplifier circuit, and so on.

The memory cell array 20 may be connected to the page buffer 34 through the plurality of bit lines BL and may be connected to the row decoder 32 through the plurality of word lines WL, the plurality of string select lines SSL, and the ground select line GSL. A plurality memory cells included in the memory cell blocks BLK1, BLK2, . . . , BLKn in the memory cell array 20 may be flash memory cells. The memory cell array 20 may include a three-dimensional memory cell array. The three-dimensional memory cell array may include a plurality of NAND strings, and each of the plurality of NAND strings may include a plurality of memory cells connected to the plurality of word lines WL vertically stacked on a substrate.

The peripheral circuit 30 may receive an address ADDR, a command CMD, and a control signal CTRL from the outside of the semiconductor device 10 and may receive and transmit data DATA from and to an external device separated from the semiconductor device 10.

The row decoder 32 may select at least one of the plurality of memory cell blocks BLK1, BLK2, . . . , BLKn in response to the address ADDR and may select the word line WL, the string select line SSL, and the ground select line GSL of the selected memory cell block. The row decoder 32 may transmit a voltage for operating a memory to the word line WL of the selected memory cell block.

The page buffer 34 may be connected to the memory cell array 20 through the plurality of bit lines BL. The page buffer 34 may apply a voltage according to the data DATA to be stored in the memory cell array 20 to the bit line BL by operating as a write driver during a program operation and may detect the data DATA stored in the memory cell array 20 by operating as a sense amplifier during a read operation. The page buffer 34 may operate in response to a control signal PCTL provided by the control logic 38.

The data input/output circuit 36 may be connected to the page buffer 34 through a plurality of data lines DLs. The data input/output circuit 36 may receive the data DATA from a memory controller (not illustrated) during a program operation and provide program data DATA to the page buffer 34 based on a column address C_ADDR provided by the control logic 38. The data input/output circuit 36 may provide read data DATA stored in the page buffer 34 to the memory controller during a read operation based on the column address C_ADDR provided by the control logic 38.

The data input/output circuit 36 may transmit an address or command, which is input, to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and the column address C_ADDR to the data input/output circuit 36. The control logic 38 may generate various internal control signals used in the semiconductor device 10 in response to the control signal CTRL. For example, the control logic 38 may adjust levels of voltages provided to the plurality of word lines WL and the plurality of bit lines BL when a memory operation, such as a program operation or an erase operation, is performed.

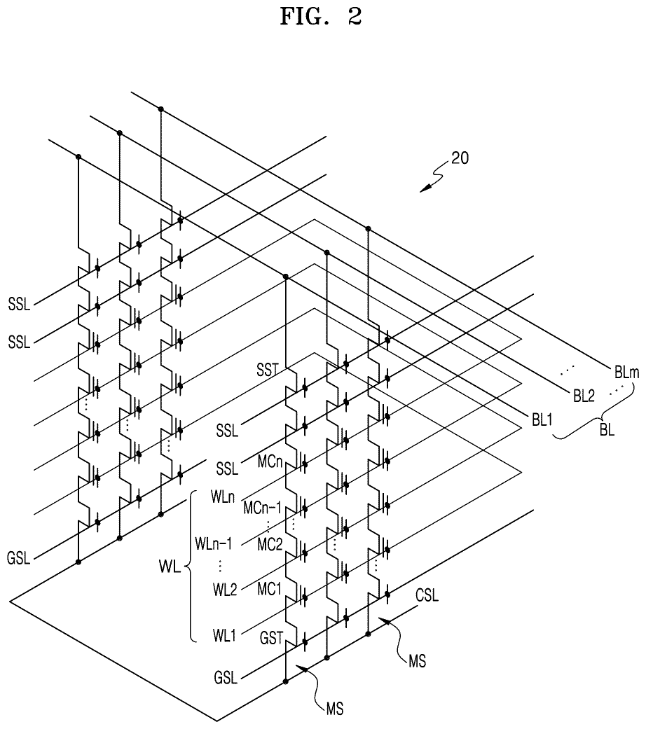

FIG. 2 is an equivalent circuit diagram of the memory cell array 20 of a semiconductor device, according to an example embodiment.

Referring to FIG. 2, the memory cell array 20 may include a plurality of memory cell strings MS. The memory cell array 20 may include a plurality of bit lines BL (BL1, BL2, . . . , BLm), a plurality of word lines WL (WL1, WL2, . . . , WLn−1, and WLn), at least one string select line SSL, at least one ground select line GSL, and a common source line CSL. The plurality of memory cell strings MS may be formed between the plurality of bit lines BL (BL1, BL2, . . . , BLm) and the common source line CSL. Although FIG. 2 illustrates a case where each of the plurality of memory cell strings MS includes two string select lines SSL, the inventive concepts are not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2, . . . , MCn−1, and MCn. A drain region of the string select transistor SST may be connected to the bit line BL (BL1, BL2, . . . , or BLm), and a source region of the ground select transistor GST may be connected to the common source line CSL. Source regions of a plurality of ground select transistors GST may be commonly connected to the common source line CSL.

The string select transistor SST may be connected to the string select line SSL, and the ground select transistor GST may be connected to the ground select line GSL. A plurality of memory cell transistors MC1, MC2, . . . , MCn−1, and MCn may be respectively connected to the plurality of word lines WL (WL1, WL2, . . . , WLn−1, and WLn).

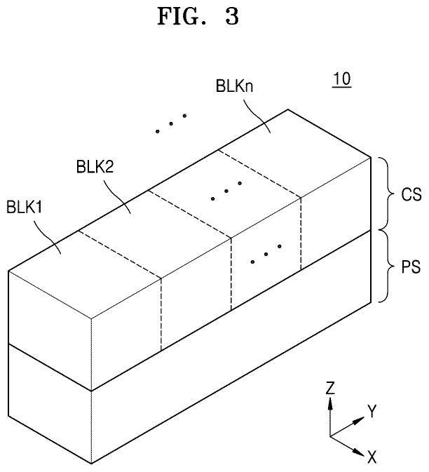

FIG. 3 is a perspective view schematically illustrating the semiconductor device 10 according to an example embodiment.

The semiconductor device 10 may include a cell array structure CS and a peripheral circuit structure PS that overlap each other in a vertical direction (a Z direction). The cell array structure CS may include the memory cell array 20 described with reference to FIGS. 1 and 2, and the peripheral circuit structure PS may include the peripheral circuit 30 described with reference to FIG. 1.

The cell array structure CS may include a plurality of memory cell blocks BLK1, BLK2, . . . , BLKn. Each of the plurality of memory cell blocks BLK1, BLK2, . . . , BLKn may include memory cells arranged three-dimensionally.

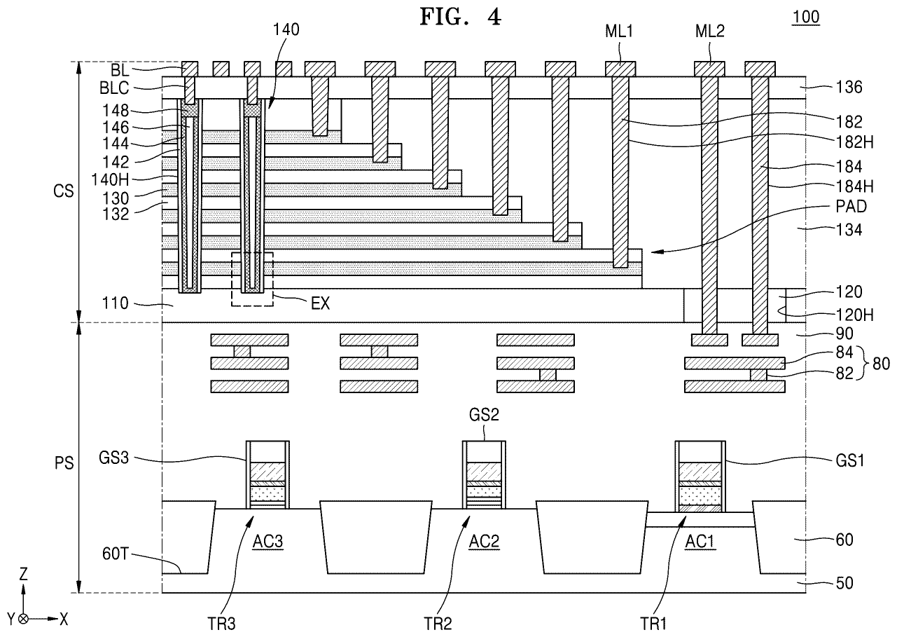

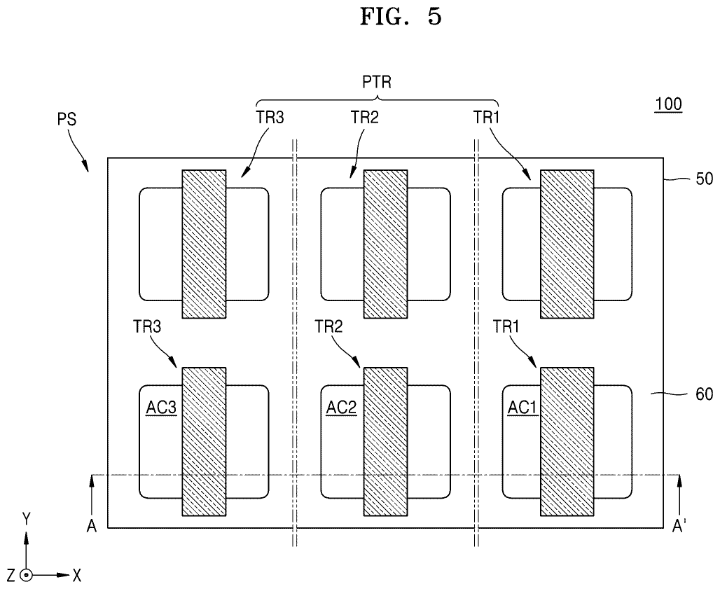

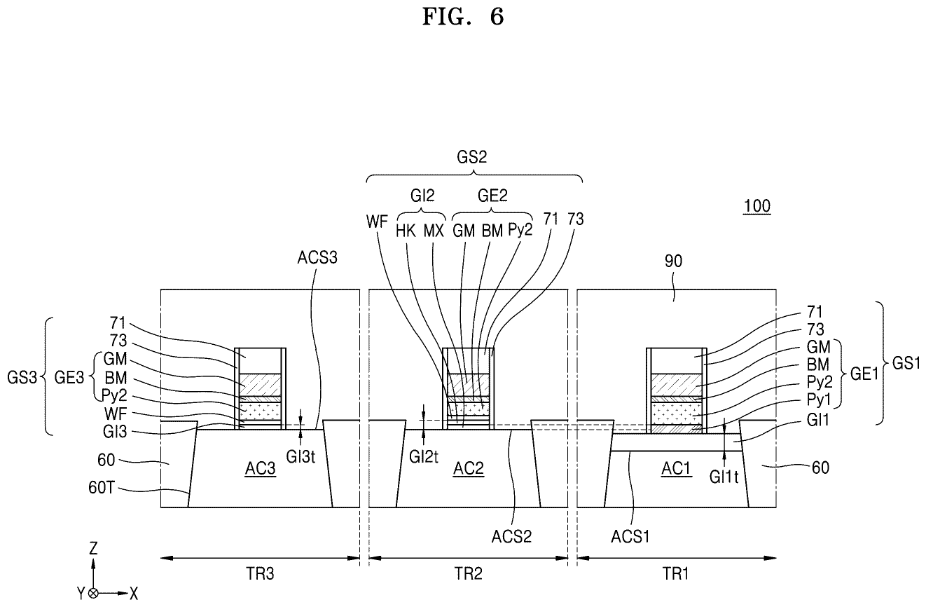

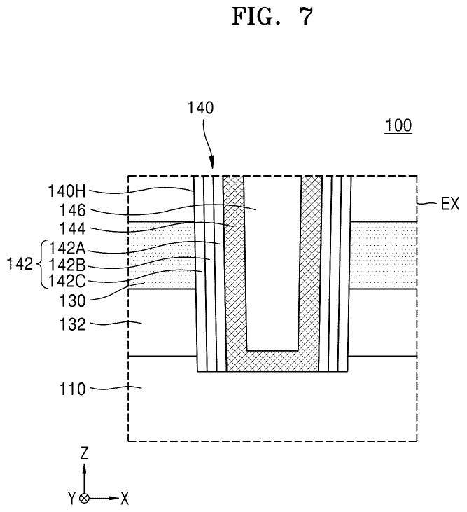

FIG. 4 is a cross-sectional view illustrating a semiconductor device 100 according to an example embodiment. FIG. 5 is a layout diagram illustrating a peripheral circuit structure of the semiconductor device 100 of FIG. 4. FIG. 6 is a cross-sectional view taken along line A-A′ of FIG. 5. FIG. 7 is an enlarged cross-sectional view of a portion EX of FIG. 4.

Referring to FIGS. 4 to 7, the semiconductor device 100 may include a peripheral circuit structure PS and a cell array structure CS, which is on the peripheral circuit structure PS to overlap the peripheral circuit structure PS in a vertical direction (a Z direction).

The peripheral circuit structure PS may include a substrate 50, peripheral circuit transistors PTRs on the substrate 50, and peripheral circuit wiring structures 80 that connect the peripheral circuit transistors PTRs to each other or connect the peripheral circuit transistors PTRs to components in the cell array structure CS, respectively.

The substrate 50 may include a semiconductor material, such as a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or an epitaxial layer. In an example embodiment, the substrate 50 may include a silicon-on-insulator (SOI) substrate, or a germanium-on-insulator (GeOI) substrate.

Active regions AC1, AC2, and AC3 on the substrate 50 may be defined by a device isolation layer 60. The device isolation layer 60 may be in a device isolation layer trench 60T formed in the substrate 50. In some example embodiments, the device isolation layer 60 may include silicon oxide, silicon nitride, silicon oxynitride, or a combination thereof.

The peripheral circuit transistors PTRs may be formed on the active regions AC1, AC2, and AC3, respectively. The peripheral circuit transistors PTRs may configure a plurality of peripheral circuits included in the peripheral circuit structure PS. The plurality of peripheral circuits configured with the peripheral circuit transistors PTRs may include various circuits included in the peripheral circuit 30 described with reference to FIG. 1. In some example embodiments, the plurality of peripheral circuits may include the row decoder 32, the page buffer 34, the data input/output circuit 36, and the control logic 38 illustrated in FIG. 1 and a common source line driver (not illustrated).

The peripheral circuit transistor PTR may include a first transistor TR1, a second transistor TR2, and a third transistor TR3. The first transistor TR1 is on the first active region AC1, the second transistor TR2 is on the second active region AC2, and the third transistor TR3 is on the third active region AC3. In some example embodiments, an upper surface ACS1 of the first active region AC1, an upper surface ACS2 of the second active region AC2, and an upper surface ACS3 of the third active region AC3 may be placed at a lower vertical level than an upper surface of the device isolation layer 60.

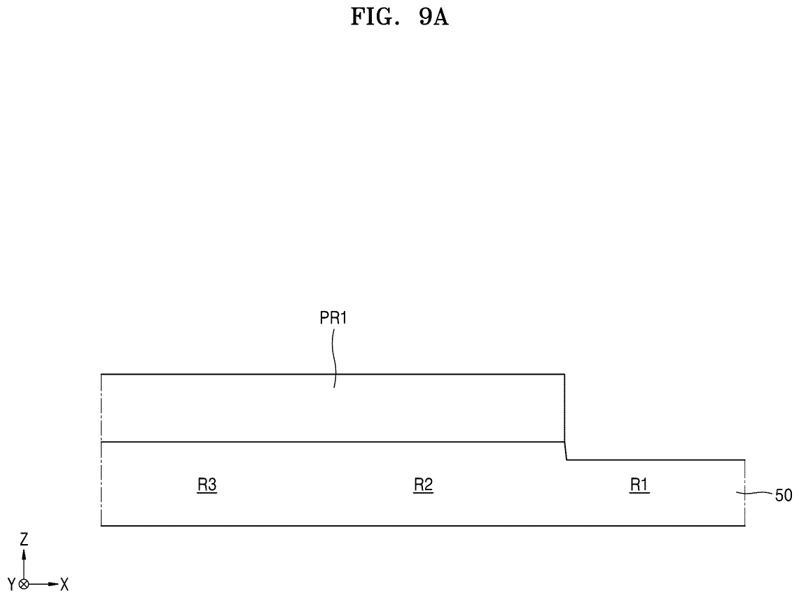

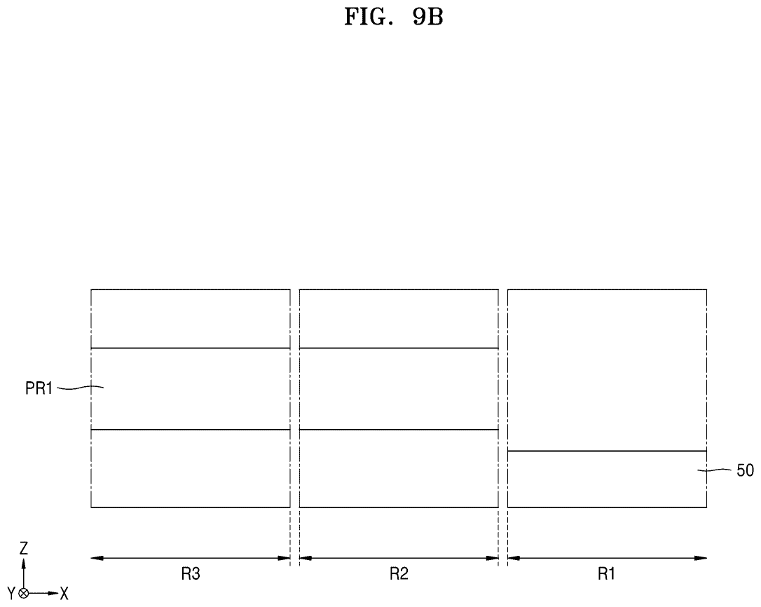

In some example embodiments, the upper surface ACS1 of the first active region AC1 may be placed at a lower vertical level than the upper surface ACS2 of the second active region AC2 and the upper surface ACS3 of the third active region AC3. The reason may be that a first region R1 of the substrate 50 corresponding to the first active region AC1 is etched to form a first gate insulating layer GI1 of the first transistor TR1 and a first semiconductor layer Py1 included in a first gate electrode GE1 of the first transistor TR1 as described below with reference to FIGS. 9A and 9B,

In some example embodiments, the upper surface ACS2 of the second active region AC2 may be at the same vertical level as the upper surface ACS3 of the third active region AC3.

In some example embodiments, the first transistor TR1 may have a first threshold voltage, the second transistor TR2 may have a second threshold voltage that is lower than the first threshold voltage, and the third transistor TR3 may have a third threshold voltage that is lower than the first and second threshold voltages.

In some example embodiments, the first transistor TR1 may be in a high-voltage region (not illustrated) of the peripheral circuit structure PS, the second transistor TR2 may be in a mid-voltage region (not illustrated) of the peripheral circuit structure PS, and the third transistor TR3 may be in a low-voltage region (not illustrated) of the peripheral circuit structure PS.

The first transistor TR1 may include a first gate structure GS1. The first gate structure GS1 may include the first gate insulating layer GI1, the first gate electrode GE1, a gate capping layer 71, and a gate spacer 73.

The first gate insulating layer GI1 may cover entirety of the upper surface ACS1 of the first active region AC1. Accordingly, the first gate insulating layer GI1 may be in contact with a sidewall of the device isolation layer 60. However, the inventive concepts are not limited thereto, and the first gate insulating layer GI1 may cover only a part of the upper surface ACS1 of the first active region AC1. The first gate insulating layer GI1 may include at least one selected from a silicon oxide film, a silicon nitride film, and a silicon oxynitride film.

The first gate electrode GE1 may be on the first gate insulating layer GI1. The first gate electrode GE1 may include the first semiconductor layer Py1, a second semiconductor layer Py2, a first metal layer BM, and a second metal layer GM. The first semiconductor layer Py1 and the second semiconductor layer Py2 may each include, for example, doped polysilicon. The first metal layer BM may include, for example, a titanium nitride film, a titanium silicon nitride film, or a combination thereof. The second metal layer GM may include, for example, tungsten, aluminum, molybdenum, titanium, or a combination thereof.

Although not illustrated in FIGS. 4 to 6, source/drain regions (not illustrated) may be further formed in the first active regions AC1 on both sides of the first gate structure GS1. For example, the source/drain regions may be doped with impurities.

The gate capping layer 71 may be on the first gate electrode GE1, and the gate spacer 73 may be on a sidewall of each of the first gate insulating layer GI1, the first gate electrode GE1, and the gate capping layer 71. The gate capping layer 71 and the gate spacer 73 may each include silicon nitride.

The second transistor TR2 may include a second gate structure GS2. The second gate structure GS2 may include a second gate insulating layer GI2, a work function metal layer WF, a second gate electrode GE2, a gate capping layer 71, and a gate spacer 73.

The second gate insulating layer GI2 may cover only a part of the upper surface ACS2 of the second active region AC2. Accordingly, the second gate insulating layer GI2 may be horizontally separated from a sidewall of the device isolation layer 60 with the interlayer insulating layer 90 therebetween. However, the inventive concepts are not limited thereto, and the second gate insulating layer GI2 may cover an entirety of the upper surface ACS2 of the second active region AC2.

The second gate insulating layer GI2 may include a first insulating layer MX and a second insulating layer HK that are sequentially stacked on the second active region AC2. For example, the first insulating layer MX may include at least one selected from a silicon oxide film, a silicon nitride film, and a silicon oxynitride film. For example, the second insulating layer HK may include a high dielectric film having a higher dielectric constant than a silicon oxide film. For example, the high dielectric film may include at least one selected from a hafnium oxide film, a hafnium silicon oxide film, a hafnium aluminum oxide film, a lanthanum oxide film, a zirconium oxide film, a tantalum oxide film, and a titanium oxide film. In some example embodiments, an interface layer (not illustrated) may be between the first insulating layer MX and the second insulating layer HK. For example, the interface layer may include at least one selected from a silicon oxide film, a silicon nitride film, and a silicon oxynitride film.

The work function metal layer WF may be on the second gate insulating layer GI2. The work function metal layer WF may perform a function of adjusting a work function of the second gate electrode GE2. The work function metal layer WF may include at least one selected from, for example, a titanium nitride film, a titanium carbonitride film, a tungsten nitride film, and a tungsten carbonitride film.

The second gate electrode GE2 may be on the work function metal layer WF. The second gate electrode GE2 may include a second semiconductor layer Py2, the first metal layer BM, and the second metal layer GM. The second semiconductor layer Py2, the first metal layer BM, and the second metal layer GM of the second gate electrode GE2 may each include a material that is the same as or substantially similar to a material as the second semiconductor layer Py2, the first metal layer BM, and the second metal layer GM of the first gate electrode GE1.

Although not illustrated in FIGS. 4 to 6, source/drain regions (not illustrated) may be further formed in the second active regions AC2 on both sides of the second gate structure GS2. For example, the source/drain regions may be doped with impurities.

The gate capping layer 71 may be on the second gate electrode GE2, and the gate spacer 73 may be on a sidewall of each of the second gate insulating layer GI2, the work function metal layer WF, the second gate electrode GE2, and the gate capping layer 71.

The third transistor TR3 may include a third gate structure GS3. The third gate structure GS3 may include a third gate insulating layer GI3, a work function metal layer WF, a third gate electrode GE3, a gate capping layer 71, and a gate spacer 73.

The third gate insulating layer GI3 may cover only a part of the upper surface ACS3 of the third active region AC3. Accordingly, the third gate insulating layer GI3 may be horizontally separated from a sidewall of the device isolation layer 60 with the interlayer insulating layer 90 therebetween. However, the inventive concepts are not limited thereto, and the third gate insulating layer GI3 may cover an entirety of the upper surface ACS3 of the third active region AC3.

The third gate insulating layer GI3 may include a material that is the same as or substantially similar to a material of the second insulating layer HK of the second gate insulating layer GI2. For example, the third gate insulating layer GI3 may include a high dielectric film having a higher dielectric constant than a silicon oxide film. In some example embodiments, an interface layer (not illustrated) may be between the third gate insulating layer GI3 and the third active region AC3. For example, the interface layer may include at least one selected from a silicon oxide film, a silicon nitride film, and a silicon oxynitride film.

The work function metal layer WF may be on the third gate insulating layer GI3. The work function metal layer WF may perform a function of adjusting a work function of the third gate insulating layer GI3. The work function metal layer WF of the third gate structure GS3 may include a material that is the same as or substantially similar to the work function metal layer WF of the second gate structure GS2.

The third gate electrode GE3 may be on the work function metal layer WF. The third gate electrode GE3 may include a second semiconductor layer Py2, a first metal layer BM, and a second metal layer GM. The second semiconductor layer Py2, the first metal layer BM, and the second metal layer GM of the third gate electrode GE3 may each include a material that is the same or substantially similar to a material of a corresponding one of the second semiconductor layer Py2, the first metal layer BM, and the second metal layer GM of the first gate electrode GE1.

Although not illustrated in FIGS. 4 to 6, source/drain regions (not illustrated) may be further formed in the third active region AC3 on both sides of the third gate structure GS3. For example, the source/drain regions may be doped with impurities.

The gate capping layer 71 may be on the third gate electrode GE3, and the gate spacer 73 may be on a sidewall of each of the third gate insulating layer GI3, the work function metal layer WF, the third gate electrode GE3, and the gate capping layer 71.

In some example embodiments, the vertical thickness GI1t of the first gate insulating layer GI1 is greater than the vertical thickness GI2t of the second gate insulating layer GI2. The vertical thickness GI2t may be greater than the vertical thickness GIt3 of the third gate insulating layer GI3.

In some example embodiments, a horizontal width of the first gate structure GS1 may be greater than a horizontal width of the second gate structure GS2 and a horizontal width of the third gate structure GS3. In some example embodiments, the horizontal width of the second gate structure GS2 may be equal to the horizontal width of the third gate structure GS3.

In some example embodiments, an upper surface of the first gate structure GS1, an upper surface of the second gate structure GS2, and an upper surface of the third gate structure GS3 may all be at the same vertical level.

In some example embodiments, an upper surface of the first gate insulating layer GI1 of the first gate structure GS1 may be at a lower vertical level than the upper surface ACS2 of the second active region AC2 and the upper surface ACS3 of the third active region AC3. Accordingly, a lower surface of the first semiconductor layer Py1 of the first gate structure GS1 in contact with the upper surface of the first gate insulating layer GI1 of the first gate structure GS1 may also be at a lower vertical level than the upper surface ACS2 of the second active region AC2 and the upper surface ACS3 of the third active region AC3.

In some example embodiments, an upper surface of the first semiconductor layer Py1 of the first gate structure GS1 may be at the same vertical level as an upper surface of the first insulating layer MX of the second gate structure GS2 and an upper surface of the third gate insulating layer GI3 of the third gate structure GS3.

The peripheral circuit wiring structure 80 may include a plurality of contacts 82 and a plurality of wiring layers 84. The plurality of wiring layers 84 may have a multi-layer structure including a plurality of metal layers at different vertical levels. At least some of the plurality of wiring layers 84 may be electrically connected to the peripheral circuit transistor PTR. The plurality of contacts 82 may connect the peripheral circuit transistor PTR to some selected from among the plurality of wiring layers 84.

The interlayer insulating layer 90 may cover the peripheral circuit transistor PTR and the peripheral circuit wiring structure 80. The interlayer insulating layer 90 may include a silicon oxide film, a silicon nitride film, a SiON film, a SiOCN film, or a combination thereof.

A common source plate 110 may be on the interlayer insulating layer 90. The common source plate 110 may function as the common source line CSL (see FIG. 2) that supplies a current to vertical memory cells formed in the cell array structure CS. The common source plate 110 may have an opening 120H.

In some example embodiments, the common source plate 110 may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. In some example embodiments, the common source plate 110 may include a semiconductor doped with impurities. For example, the common source plate 110 may include polysilicon doped with an n-type impurity. In some example embodiments, the common source plate 110 may have a crystal structure including at least one selected from single crystal, amorphous, and polycrystalline.

An insulating plug 120 may fill the inside of the opening 120H of the common source plate 110. The insulating plug 120 may have an upper surface at the same vertical level as an upper surface of the common source plate 110. The insulating plug 120 may include, for example, silicon oxide.

A plurality of gate lines 130 and a plurality of insulating layers 132 may be alternately stacked on the common source plate 110 in the vertical direction (the Z direction).

The plurality of gate lines 130 may each include metal, such as tungsten, nickel, cobalt, or tantalum, metal silicide, such as tungsten silicide, nickel silicide, cobalt silicide, or tantalum silicide, doped polysilicon, titanium nitride, tantalum nitride, tungsten nitride, or a combination thereof. The plurality of insulating layers 132 may each include silicon oxide.

In some example embodiments, the plurality of gate lines 130 may correspond to the ground select line GSL (see FIG. 2), the word lines WL (WL1, WL2, . . . , WLn−1, and WLn) (see FIG. 2), and at least one string select line SSL (see FIG. 2) that constitute the memory cell string MS (see FIG. 2). For example, the bottom gate line 130 may function as the ground select line GSL, the top two gate lines 130 may function as the string select lines SSL, and the other gate lines 130 function as word lines WL. Accordingly, the memory cell string MS (see FIG. 2) may be provided in which the ground select transistor GST (see FIG. 2), the memory cell transistors MC1, MC2, . . . , MCn−1, and MCn therebetween (see FIG. 2), and the string select transistor SST (see FIG. 2) are connected in series. In some example embodiments, at least one of the plurality of gate lines 130 may function as a dummy word line, but the inventive concepts are not limited thereto.

A plurality of channel structures 140 may extend in the vertical direction (the Z direction) from an upper surface of the common source plate 110 through the plurality of gate lines 130 and the plurality of insulating layers 132. The plurality of channel structures 140 may be arranged to be separated from each other at desired (or alternatively, predetermined) intervals in the first horizontal direction (the X direction) and the second horizontal direction (the Y direction). The plurality of channel structures 140 may each include a gate insulating layer 142, a channel layer 144, a buried insulating layer 146, and a conductive plug 148 provided in a channel hole 140H.

The gate insulating layer 142 and the channel layer 144 may be sequentially arranged on a sidewall of the channel hole 140H. For example, the gate insulating layer 142 may be conformally arranged on the sidewall of the channel hole 140H, and the channel layer 144 may be conformally arranged on the sidewall and a bottom surface of the channel hole 140H.

As illustrated in FIG. 7, the gate insulating layer 142 may include a tunneling dielectric layer 142A, a charge storage layer 142B, and a blocking dielectric layer 142C sequentially arranged on an outer wall of the channel layer 144. Relative thicknesses of the tunneling dielectric layer 142A, the charge storage layer 142B, and the blocking dielectric layer 142C forming the gate insulating layer 142 are not limited to the thicknesses illustrated in FIG. 7 and may be changed in various ways.

The tunneling dielectric layer 142A may include silicon oxide, hafnium oxide, aluminum oxide, zirconium oxide, tantalum oxide, or so on. The charge storage layer 142B may be a region in which electrons passing through the tunneling dielectric layer 142A from the channel layer 144 may be stored, and may include silicon nitride, boron nitride, silicon boron nitride, or polysilicon doped with impurities. The blocking dielectric layer 142C may include silicon oxide, silicon nitride, or a metal oxide having a higher dielectric constant than silicon oxide. The metal oxide may include hafnium oxide, aluminum oxide, zirconium oxide, tantalum oxide, or a combination thereof.

The channel layer 144 may have a cylindrical shape. The channel layer 144 may include doped polysilicon or undoped polysilicon. In some example embodiments, the channel layer 144 may be in contact with an upper surface of the common source plate 110 at the bottom of the channel hole 140H. In some example embodiments, as illustrated in FIG. 4, a bottom surface of the channel layer 144 may be at a lower vertical level than the upper surface of the common source plate 110 but inventive concepts are not limited thereto.

The buried insulating layer 146 may fill an internal space of the channel layer 144. The buried insulating layer 146 may include, for example, silicon oxide, silicon nitride, silicon oxynitride, or a combination thereof. In some example embodiments, the buried insulating layer 146 may be omitted. In this case, the channel layer 144 may have a pillar shape without an internal space.

The conductive plug 148 may be in contact with the channel layer 144 on an upper side of the channel hole 140H and may block an entrance of the channel hole 140H. The conductive plug 148 may include, for example, a doped polysilicon film.

The plurality of gate lines 130 may extend to have a shorter length in the first horizontal direction (the X direction) as a distance from the upper surface of the common source plate 110 increases. That is, the plurality of gate lines 130 may have a step shape. In this case, edge portions of the plurality of gate lines 130 arranged in a step shape may be referred to as a pad structure PAD. A cover insulating layer 134 may be on the pad structure PAD, and an upper insulating layer 136 may be on the plurality of insulating layers 132 and the cover insulating layer 134. The cover insulating layer 134 and the upper insulating layer 136 may each include an oxide film, a nitride film, or a combination thereof.

A cell contact 182 connected to the pad structure PAD may be in a cell contact hole 182H penetrating the cover insulating layer 134 and the upper insulating layer 136, and a conductive through-via 184 may be in a through-hole 184H penetrating the cover insulating layer 134, the upper insulating layer 136, and the insulating plug 120. The cell contact 182 may be connected to one gate line 130 selected from among the plurality of gate lines 130. The cell contact 182 may be in contact with the pad structure PAD of the selected one gate line 130 and be connected to the selected one gate line 130 through the pad structure PAD. The conductive through-via 184 may be connected to the peripheral circuit transistor PTR through the wiring layer 84. The cell contact 182 and the conductive through-via 184 may each include tungsten, titanium, tantalum, copper, aluminum, titanium nitride, tantalum nitride, tungsten nitride, or a combination thereof.

A bit line contact BLC may pass through the upper insulating layer 136 to be connected to the channel structure 140. The bit line BL may be on the upper insulating layer 136 and be connected to the bit line contact BLC. Also, a first wiring line ML1 connected to the cell contact 182 and a second wiring line ML2 connected to the conductive through-via 184 may be arranged on the upper insulating layer 136.

In general, the peripheral circuit structure PS may include various peripheral circuit transistors PTR that provide power and signals to the cell array structure CS to drive the cell array structure CS. In this case, in order to increase the capacitance of a transistor and reduce a leakage current, a transistor (e.g., the second transistor TR2) included in a mid-voltage region and a transistor included (e.g., the third transistor TR3) in a low-voltage region may each be formed to have a gate insulating layer including a high dielectric film and a gate electrode including a metal layer. In addition, in order to increase the operational reliability, a transistor (e.g., the first transistor TR1) included in a high-voltage region may include an insulating material, such as a silicon oxide film, and may be formed to have a gate insulating layer having a relatively great thickness and a gate electrode formed of polysilicon. In order to form transistors, an insulating material, such as a silicon oxide film, may be formed for the transistor included in the high-voltage region, a high dielectric material layer and a metal material layer may be formed for the transistor included in the mid-voltage region and the transistor included in the low-voltage region, a part of the high dielectric material layer and the metal material layer formed in the high-voltage region may be removed, and then a polysilicon layer may be formed for the transistor included in the high-voltage region. In this case, in the process of removing a part of the high dielectric material layer and the metal material layer formed in the high-voltage region, the insulating material formed in the high-voltage region may be damaged. In this case, a thickness distribution of the gate insulating layer of the transistor included in the high-voltage region formed of an insulating material may be degraded due to the damage, and accordingly, the operational reliability of the transistor included in the high-voltage region may be reduced.

However, the semiconductor device 100 according to some example embodiments may be formed by forming an insulating material layer constituting the first gate insulating layer GI1, forming a semiconductor material layer constituting the first semiconductor layer Py1 on the insulating material layer, forming a high dielectric film forming the second gate insulating layer GI2 and the third gate insulating layer GI3, forming the work function metal layer WF, and removing a part of the high dielectric film and the work function metal layer WF formed on the first region R1 (see FIG. 9A) corresponding to the high-voltage region. Therefore, in the process of removing a part of the high dielectric layer and the work function metal layer WF formed on the first region R1 (see FIG. 9A) corresponding to the high-voltage region, a semiconductor material layer forming the first semiconductor layer Py1 may protect an insulating material layer forming the first gate insulating layer GI1, and thus, a thickness distribution of the first gate insulating layer GI1 may be improved, and the operation reliability of the first transistor TR1 including the first gate insulating layer GI1 may be increased.

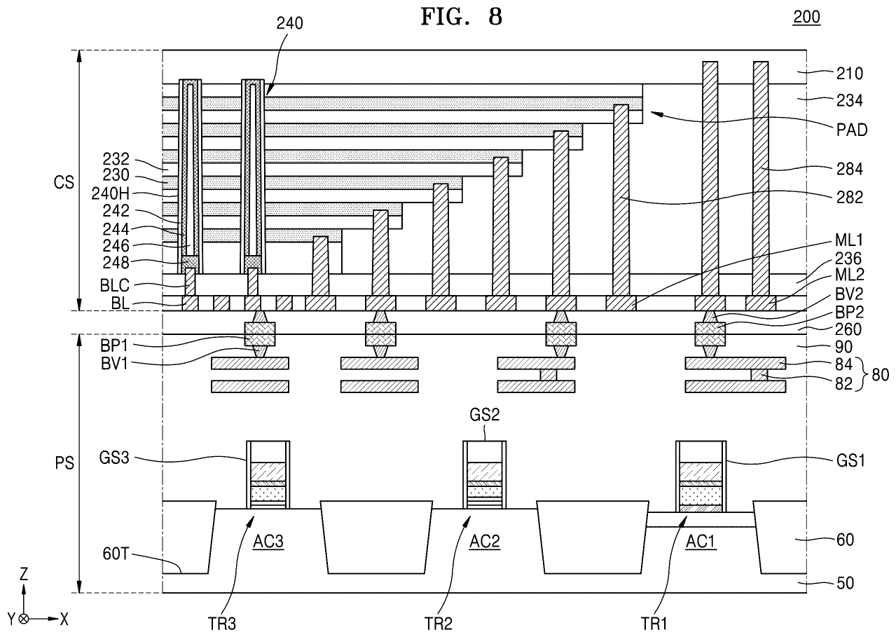

FIG. 8 is a cross-sectional view illustrating a semiconductor device 200 according to an example embodiment. Respective components of the semiconductor device 200 illustrated in FIG. 8 are the same as or substantially similar to the respective components of the semiconductor device 100 described with reference to FIGS. 4 to 7, and accordingly, following description focuses on a difference therebetween.

Referring to FIG. 8, the semiconductor device 200 may include a peripheral circuit structure PS and a cell array structure CS, which is on the peripheral circuit structure PS and overlaps the peripheral circuit structure PS in a vertical direction (the Z direction).

In one example embodiment, the semiconductor device 200 may have a chip to chip (C2C) structure. The C2C structure may be a structure obtained by forming the cell array structure CS on a first wafer, forming the peripheral circuit structure PS on a second wafer that is different from the first wafer, and then connecting the cell array structure CS to the peripheral circuit structure PS by using a bonding method. For example, the bonding method may refer to a method of electrically or physically connecting a first bonding pad BP1 of the peripheral circuit structure PS to a second bonding pad BP2 of the cell array structure CS. In some example embodiments, when each of the first bonding pad BP1 and the second bonding pad BP2 includes copper (Cu), the bonding method may be a Cu—Cu bonding method. In some example embodiments, each of the first bonding pad BP1 and the second bonding pad BP2 may also include aluminum (Al) or tungsten (W).

The peripheral circuit structure PS may include a substrate 50, peripheral circuit transistors on the substrate 50, and a peripheral circuit wiring structure 80 for connecting peripheral circuit transistors to each other or connecting the peripheral circuit transistors to components in the cell array structure CS. The peripheral circuit transistors may include a first transistor TR1, a second transistor TR2, and a third transistor TR3. Respective components of the peripheral circuit structure PS may be the same as or substantially similar to the respective components of the peripheral circuit structure PS of the semiconductor device 100 described with reference to FIGS. 4 and 7.

A plurality of first bonding pads BP1 may be arranged within an interlayer insulating layer 90. The plurality of first bonding pads BP1 may be connected to a peripheral circuit wiring structure 80 through a first bonding via BV1. In an example embodiment, an upper surface of the first bonding pad BP1 may be on the same surface as an upper surface of the interlayer insulating layer 90. The first bonding pad BP1 may include, for example, copper (Cu), gold (Au), silver (Ag), aluminum (Al), tungsten (W), titanium (Ti), tantalum (Ta), or a conductive material including a combination thereof.

The cell array structure CS may include a plurality of gate lines 230 and a plurality of insulating layers 232 that are alternately stacked in a vertical direction (the Z direction). The plurality of gate lines 230 and the plurality of insulating layers 232 may be the same as or substantially similar to the plurality of gate lines 130 and the plurality of insulating layers 132 described with reference to FIGS. 4 to 7, respectively.

The plurality of channel structures 240 may extend in the vertical direction (the Z direction) from a lower surface of the substrate 210 through the plurality of gate lines 230 and the plurality of insulating layers 232. The plurality of channel structures 240 may each include a gate insulating layer 242, a channel layer 244, a buried insulating layer 246, and a conductive plug 248 which are arranged in a channel hole 240H. The gate insulating layer 242, the channel layer 244, the buried insulating layer 246, and the conductive plug 248 that constitute each of the plurality of channel structures 240 may be the same as or substantially similar to the gate insulating layer 142, the channel layer 144, the buried insulating layer 146, and the conductive plug 148 that constitute each of the plurality of channel structure 140 described with reference to FIGS. 4 to 7, respectively.

The plurality of gate lines 230 may extend to have a shorter length in a first horizontal direction (the X direction) as the distance from the substrate 210 increases. That is, the plurality of gate lines 230 may have an inverted step shape. In this case, edge portions of the plurality of gate lines 230 arranged in an inverted step shape may be referred to as a pad structure PAD. A cover insulating layer 234 may be on the pad structure PAD, and a lower insulating layer 236 may be on the plurality of insulating layers 232 and the cover insulating layer 234. The cover insulating layer 234 and the lower insulating layer 236 may each include a material that is the same as or substantially similar to a material forming a corresponding one of the plurality of cover insulating layers 134 and the upper insulating layer 136 described with reference to FIGS. 4 to 7.

A cell contact 282 connected to the pad structure PAD may be in a cell contact hole penetrating the cover insulating layer 234 and the lower insulating layer 236, and a conductive through-via 284 may be in a through-hole that penetrates the cover insulating layer 234 and the lower insulating layer 236 and extends into the substrate 210. The cell contact 282 may be in contact with the pad structure PAD of one gate line 230 selected from among the plurality of gate lines 230 and be connected to the selected one gate line 230 through the pad structure PAD. The conductive through-via 284 may extend into the substrate 210 and be connected to the substrate 210.

A bit line contact BLC may pass through the lower insulating layer 236 and be connected to the channel structure 240. A bit line BL may be on a lower surface of the lower insulating layer 236 and be connected to the bit line contact BLC. Also, a first wiring line ML1 connected to the cell contact 282 and a second wiring line ML2 connected to the conductive through-via 284 may be arranged on the lower insulating layer 236.

At least a part of a lower surface of each of the bit line BL, the first wiring line ML1, and the second wiring line ML2 may be in contact with a second bonding via BV2. The second bonding via BV2 may connect a second bonding pad BP2 in an interlayer insulating layer 260 to at least a part of each of the bit line BL, the first wiring line ML1, and the second wiring line ML2. A lower surface of the second bonding pad BP2 may be in contact with an upper surface of a first bonding pad BP1. The second bonding pad BP2 may include, for example, copper (Cu), gold (Au), silver (Ag), aluminum (Al), tungsten (W), titanium (Ti), tantalum (Ta), or a conductive material including a combination thereof.

FIGS. 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21, 22, 23, 24, 25, and 26 are cross-sectional views illustrating a method of manufacturing a semiconductor device, according to an example embodiment.

Referring to FIGS. 9A and 9B, first, a substrate 50 having a first region R1, a second region R2, and a third region R3 may be provided. The first region R1 is a region where the first transistor TR1 (see FIG. 4) is formed, the second region R2 is a region where the second transistor TR2 (see FIG. 4) is formed, and the third region R3 is a region where the second transistor TR3 (see FIG. 4) is formed. Next, a photoresist pattern PR1 having an opening (not illustrated) that exposes the first region R1 is formed on the substrate 50, and an upper surface of the first region R1 of the substrate 50 may be removed by a desired (or alternatively, preset) thickness by using the photoresist pattern PR1 as an etch mask. By removing the upper surface of the first region R1 of the substrate 50 by the desired (or alternatively, preset) thickness, an upper surface of a first active region AC1 to be formed in the first region R1 may be at a lower vertical level than an upper surface of a second active region AC2 to be formed in the unetched second region R2 and an upper surface of a third active region AC3 to be formed the unetched third region R3.

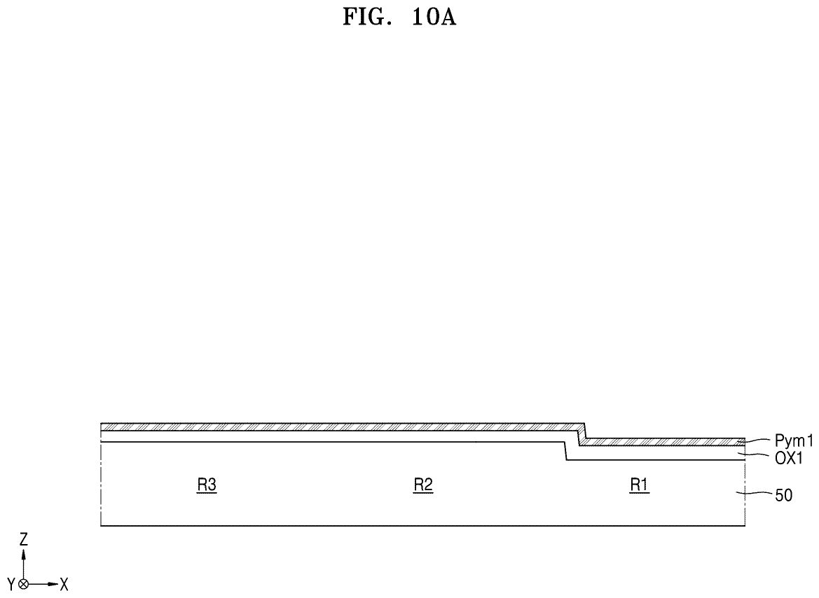

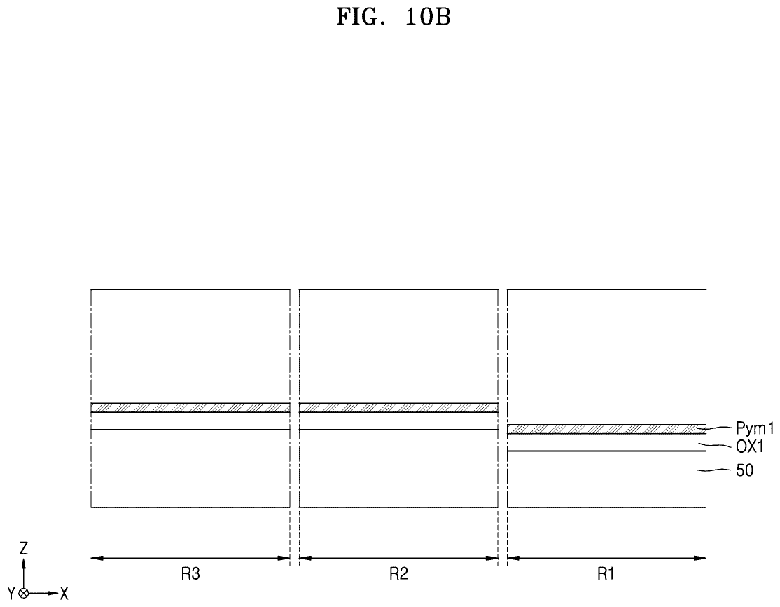

Referring to FIGS. 10A and 10B, a first photoresist pattern PR1 may be removed from a result of FIGS. 9A and 9B. Next, a first insulating material layer OX1 and a first semiconductor material layer Pym1 may be sequentially formed on upper surfaces of the first region R1, the second region R2, and the third region R3 of the substrate 50. The first insulating material layer OX1 may be the same as or substantially similar to a material forming the first gate insulating layer GI1 of the first transistor TR1 described with reference to FIGS. 4 to 7, and the first semiconductor material layer Pym1 may be the same as or substantially similar to a material forming the first semiconductor layer Py1 of the first transistor TR1. In some example embodiments, the first insulating material layer OX1 and the first semiconductor material layer Pym1 may be formed by an atomic layer deposition (ALD) process, a chemical vapor deposition (CVD) process, a plasma enhanced CVD (PECVD) process, a low pressure CVD (LPCVD) process, or so on. The first insulating material layer OX1 may be formed such that an upper surface of the first insulating material layer OX1 is at a lower vertical level than upper surfaces of the second region R2 and the third region R3. The first semiconductor material layer Pym1 may be formed such that an upper surface of the first semiconductor material layer Pym1 is at a higher vertical level than the upper surfaces of the second region R2 and the third region R3.

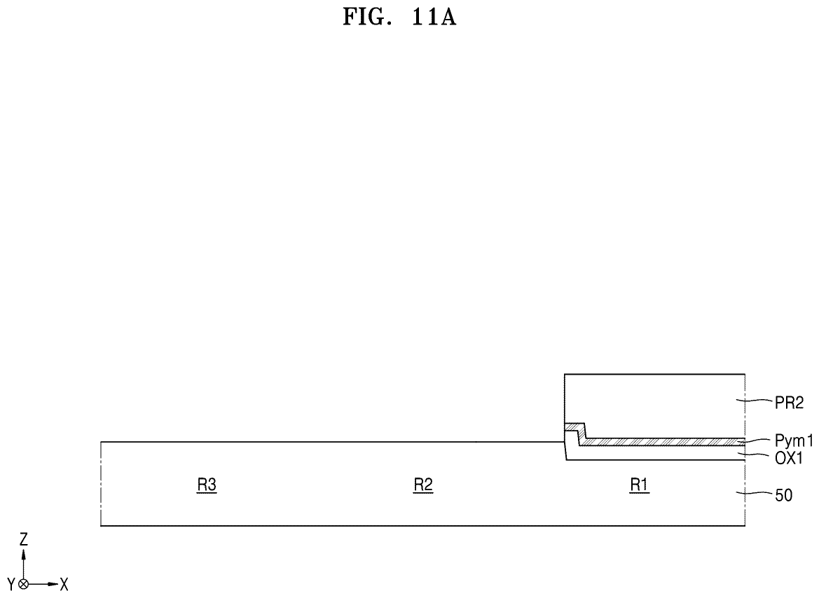

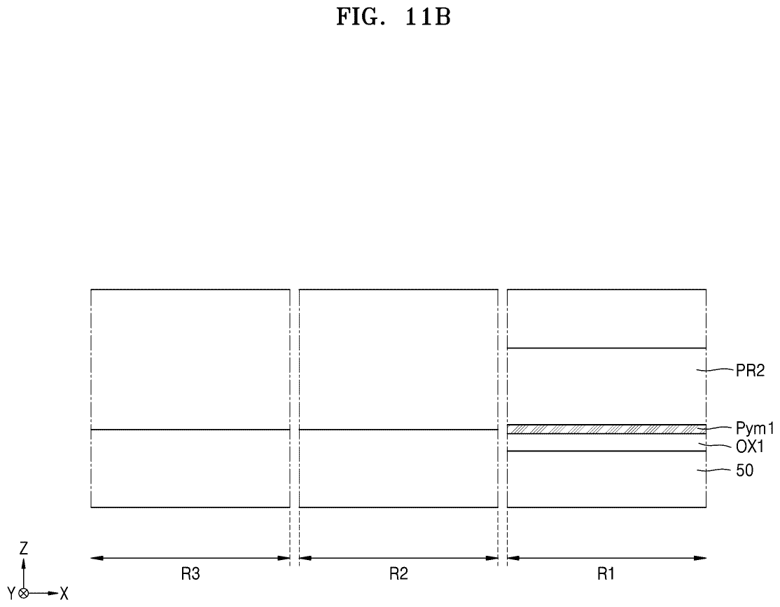

Referring to FIGS. 11A and 11B, a second photoresist pattern PR2 having an opening (not illustrated) that exposes each of the second region R2 and the third region R3 on the substrate 50 may be formed on the substrate 50. Next, the first insulating material layer OX1 and the first semiconductor material layer Pym1 formed on the second region R2 and third region R3 of the substrate 50 may be removed by using the second photoresist pattern PR2 as an etch mask. By performing the above-described process, the first insulating material layer OX1 and the first semiconductor material layer Pym1 may remain only on the first region R1 of the substrate 50.

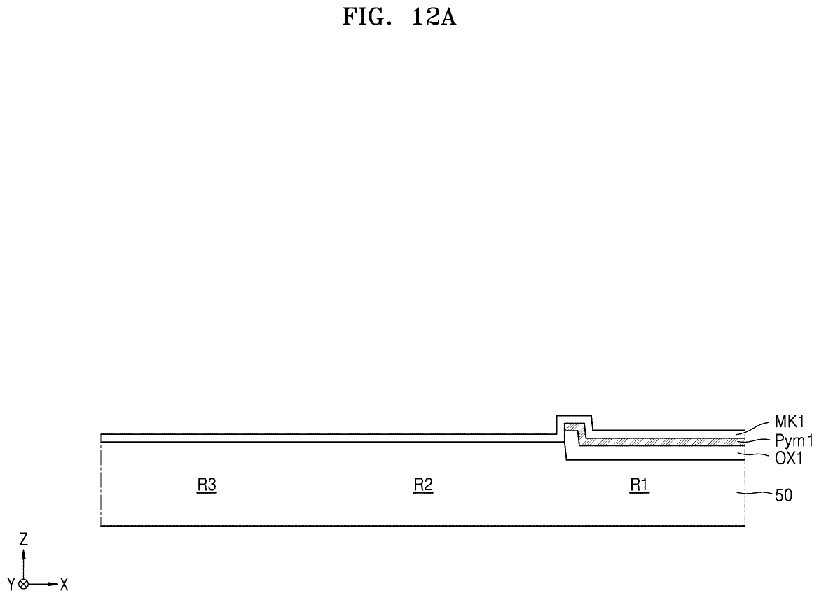

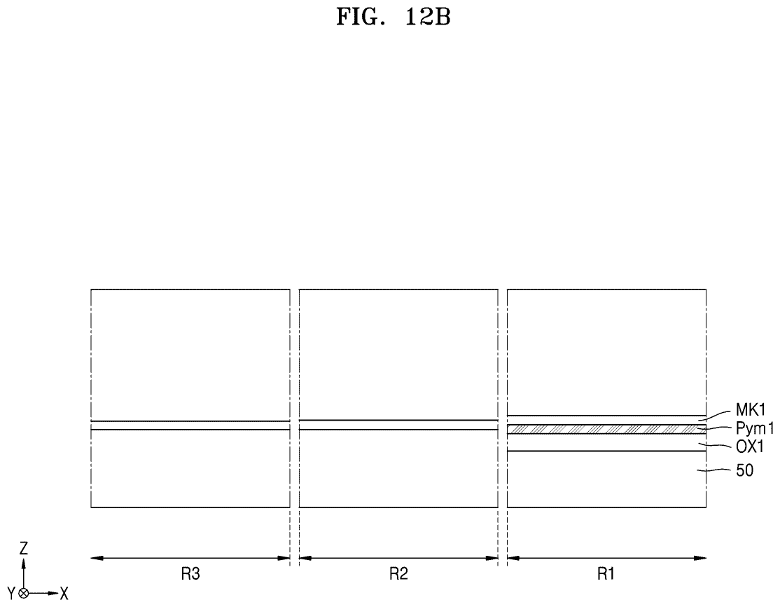

Referring to FIGS. 12A and 12B, the second photoresist pattern PR2 may be removed from a result of FIGS. 11A and 11B. Next, a mask material layer MK1 may be formed on the first region R1, the second region R2, and the third region R3 of the substrate 50. The mask material layer MK1 may cover an upper surface of the second region R2, an upper surface of the third region R3, and an upper surface of the first semiconductor material layer Pym1 formed in the first region R1. The mask material layer MK1 may include, for example, silicon nitride.

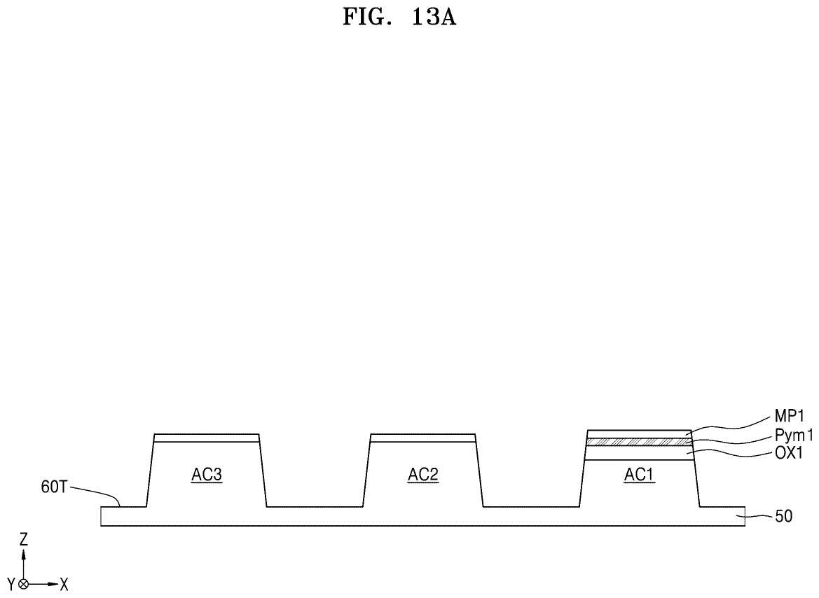

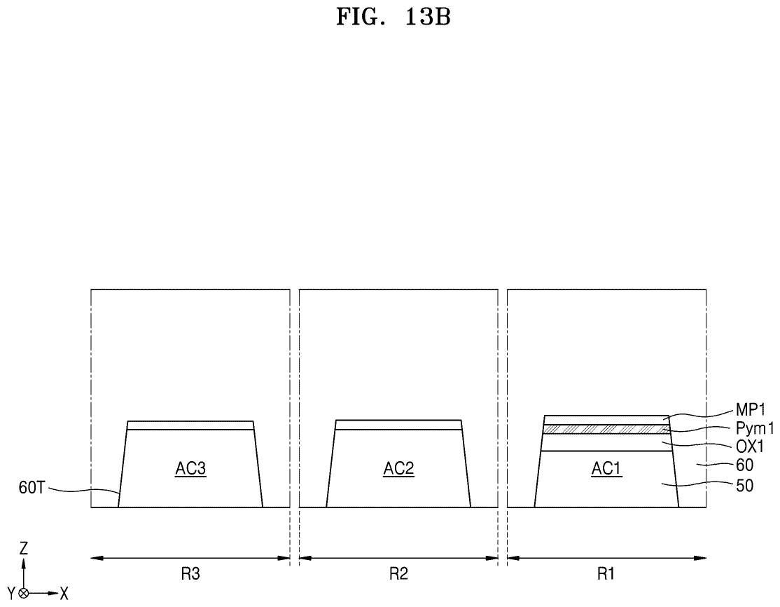

Referring to FIGS. 13A and 13B, in a result of FIGS. 12A and 12B, a mask pattern MP1 may be formed by patterning the mask material layer MK1, and a device isolation layer trench 60T may be formed by removing a part of each of the first insulating material layer OX1, the first semiconductor material layer Pym1, and the substrate 50 on the first region R1 by using the mask pattern MP1 as an etch mask.

A first active region AC1 may be defined in the first region R1 of the substrate 50 by the device isolation layer trench 60T formed through the above-described process, a second active region AC2 may be defined in the second region R2 of the substrate 50, and a third active region AC3 may be defined in the third region R3 of the substrate 50.

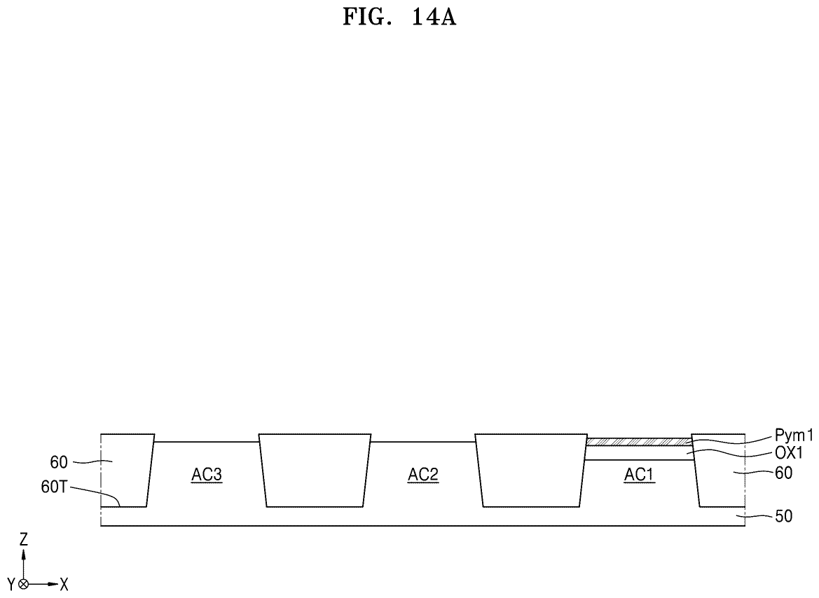

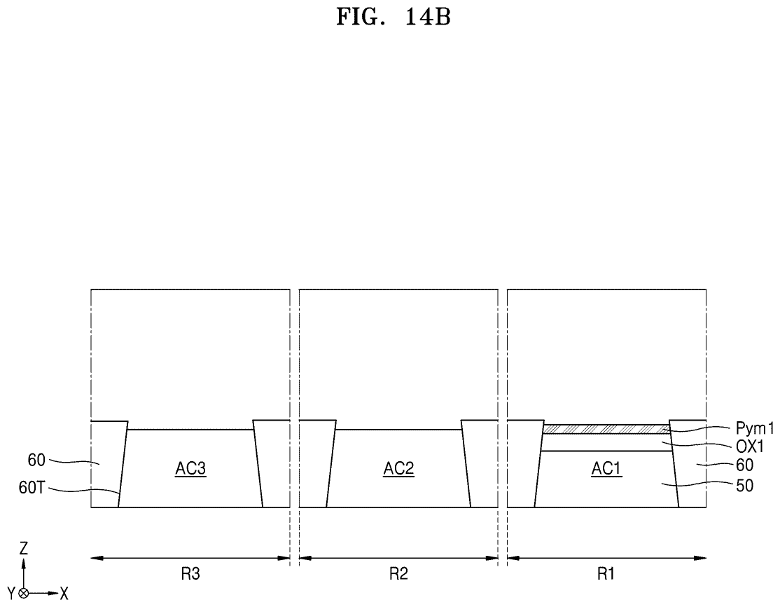

Referring to FIGS. 14A and 14B, in a result of FIGS. 13A and 13B, a device isolation layer 60 may be formed by filling the device isolation layer trench 60T with an insulating material and planarizing the insulating material. In this case, the device isolation layer 60 may be formed such that an upper surface of the device isolation layer 60 is at a higher vertical level than upper surfaces of the first, second, and third active regions AC1, AC2, and AC3. Next, the mask pattern MP1 may be removed from the first, second, and third active regions AC1, AC2, and AC3. The mask pattern MP1 may be removed by, for example, a strip process.

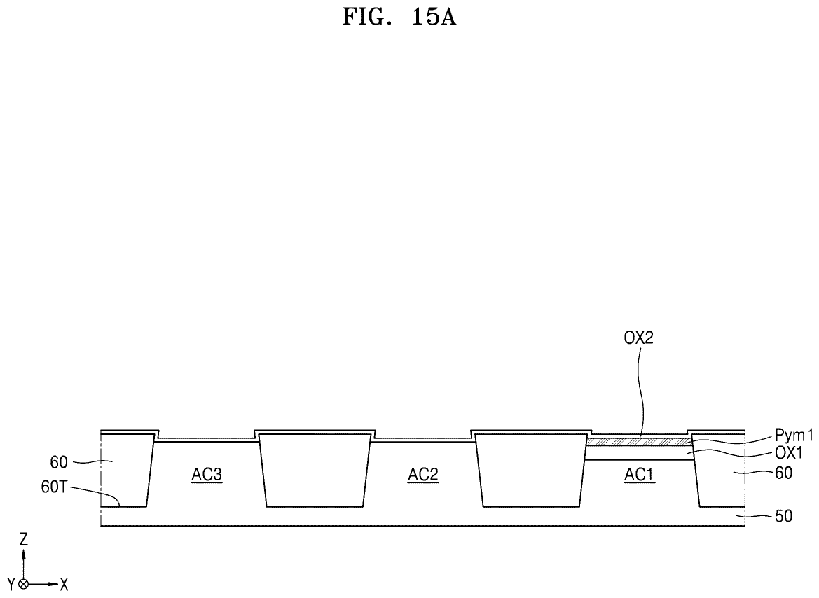

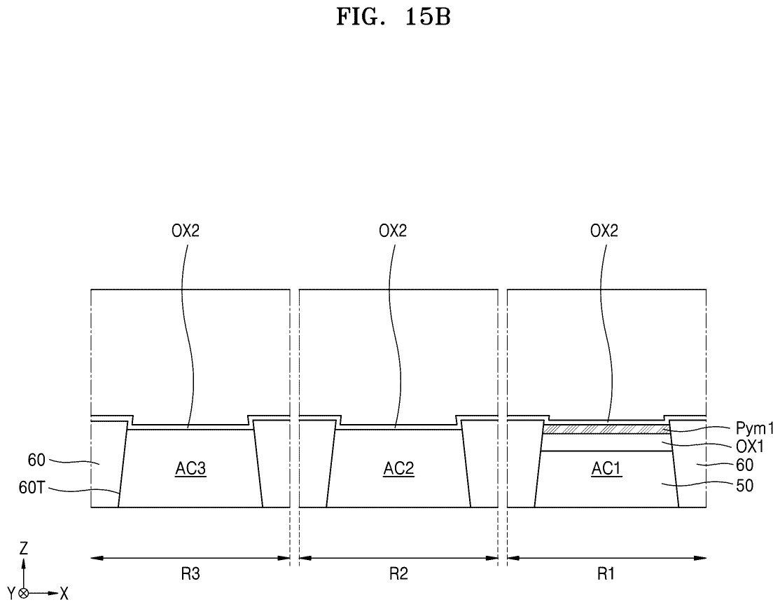

Referring to FIGS. 15A and 15B, a second insulating material layer OX2 may be formed to cover an upper surface of each of the second active region AC2, the third active region AC3, the device isolation layer 60, and the first semiconductor material layer Pym1. The second insulating material layer OX2 may include a material that is the same as or substantially similar to a material forming the first insulating layer MX included in the second gate insulating layer GI2 of the second transistor TR2 described with reference to FIGS. 4 to 7.

In some example embodiments, the second insulating material layer OX2 may be formed by an ALD process, a CVD process, a PECVD process, an LPCVD process, or so on. The second insulating material layer OX2 may be formed such that an upper surface of the second insulating material layer OX2 in the second active region AC2 is at the same vertical level as an upper surface of the first semiconductor material layer Pym1 in the first active region AC1.

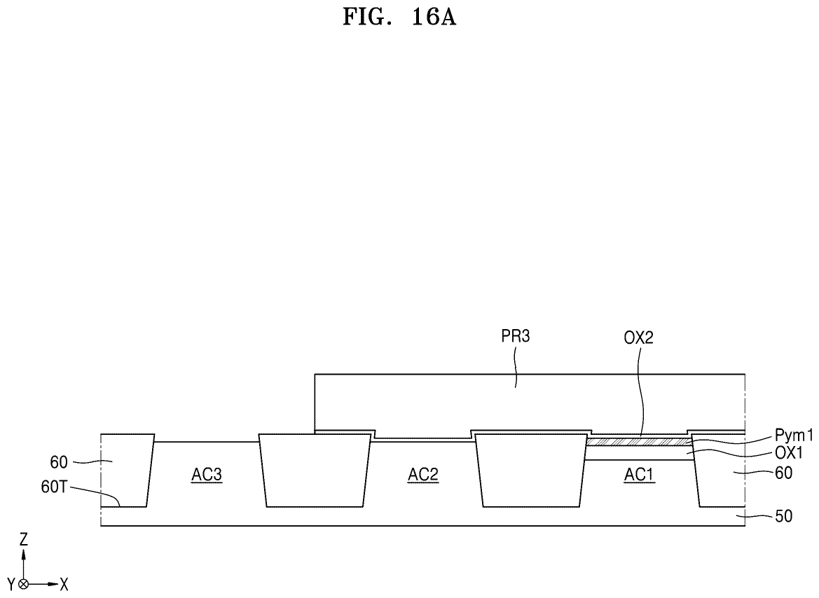

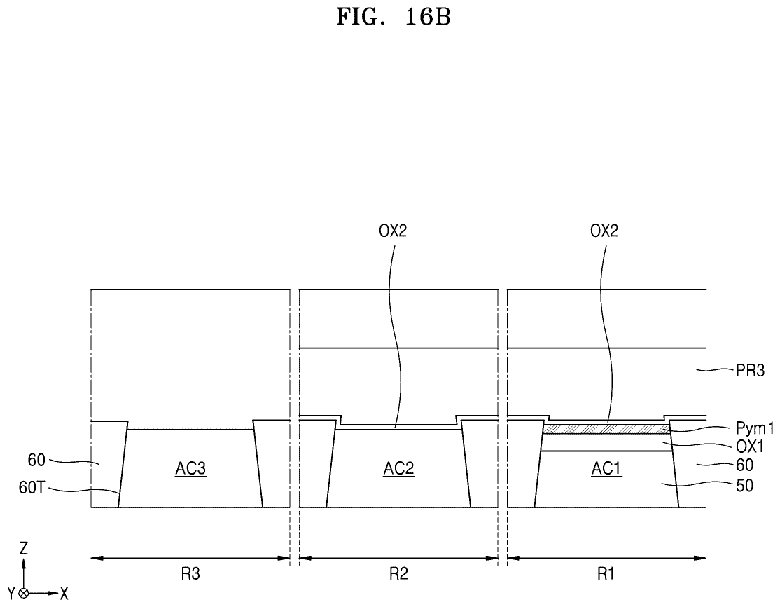

Referring to FIGS. 16A and 16B, a third photoresist pattern PR3 having an opening (not illustrated) that exposes the third active region AC3 may be formed on the substrate 50. Next, the second insulating material layer OX2 formed on the third active region AC3 of the substrate 50 may be removed by using the third photoresist pattern PR3 as an etch mask. By performing the above-described process, the second insulating material layer OX2 may remain only on the first active region AC1 and the second active region AC2 of the substrate 50.

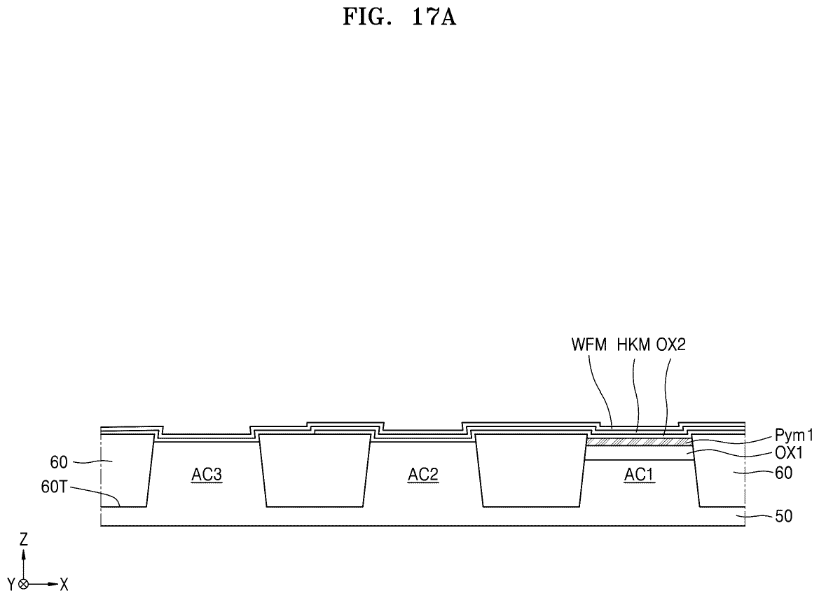

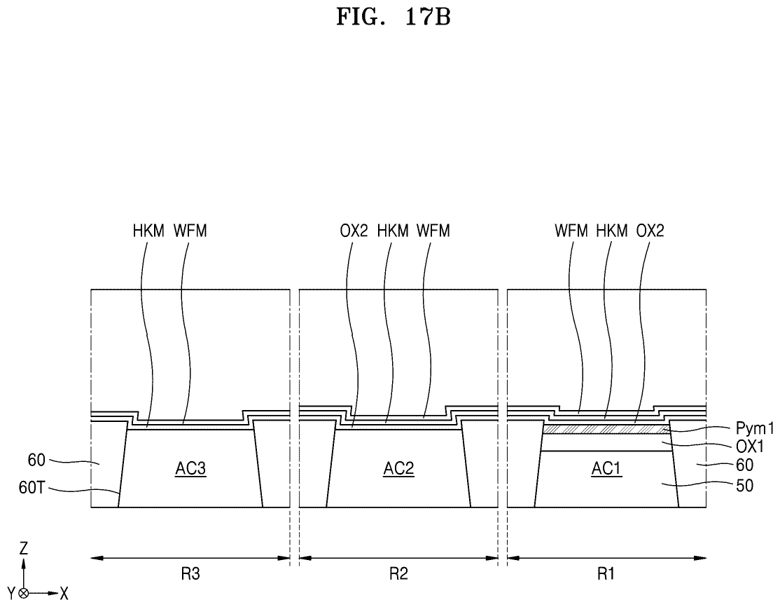

Referring to FIGS. 17A and 17B, in a result of FIGS. 16A and 16B, the third photoresist pattern PR3 may be removed from an upper surface of the second insulating material layer OX2. Next, a high dielectric material layer HKM and a work function metal material layer WFM may be sequentially formed on the third active region AC3 and the second insulating material layer OX2 on the second active region AC2 and the first active region AC1. The high dielectric material layer HKM may include a material that is the same as or substantially similar to a material forming the second insulating layer HK included in the second gate insulating layer GI2 of the second transistor TR2 described with reference to FIGS. 4 to 7, and the work function metal material layer WFM may include a material that is the same as or substantially similar to a material forming each of the work function metal layer WF of the second transistor TR2 and the work function metal layer WF of the third transistor TR3 described with reference to FIGS. 4 to 7. In some example embodiments, the high material layer HKM and the work function metal material layer WFM may each be formed by an ALD process, a CVD process, a PECVD process, an LPCVD process, or so on. The high dielectric material layer HKM may be formed such that, on the third active region (AC3), an upper surface of the high dielectric material layer HKM is at the same vertical level as an upper surface of the first semiconductor material layer Pym1 and an upper surface of the second insulating material layer OX2 on the second active region AC.

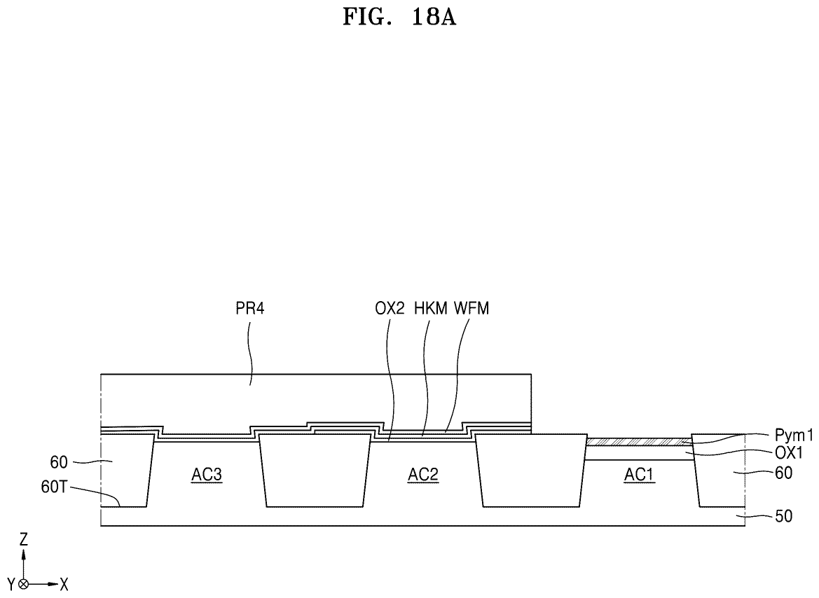

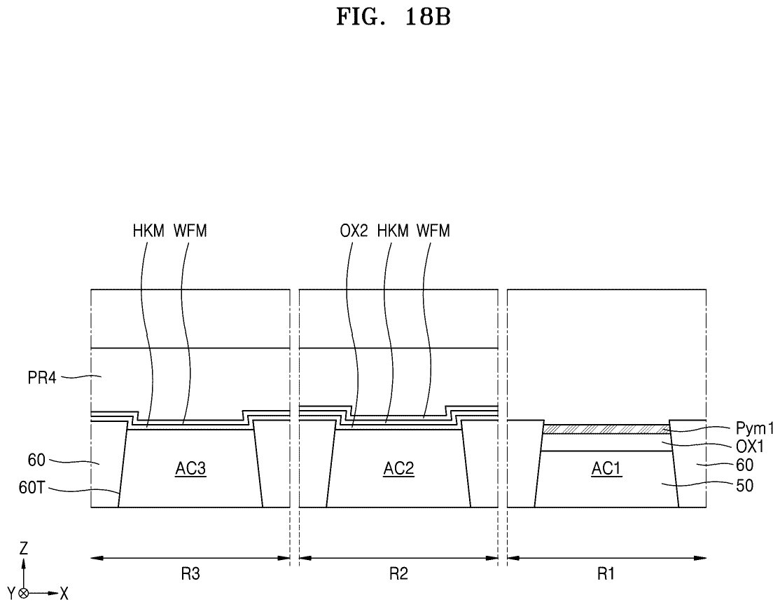

Referring to FIGS. 18A and 18B, a fourth photoresist pattern PR4 having an opening (not illustrated) that exposes the first active region AC1 may be formed on the substrate 50. Next, the second insulating material layer OX2 formed on the first active region AC1 of the substrate 50 may be removed by using the fourth photoresist pattern PR4 as an etch mask. By performing the above-described process, the second insulating material layer OX2 may remain only on the second active region AC2 of the substrate 50, and the first semiconductor material layer Pym1 may be exposed.

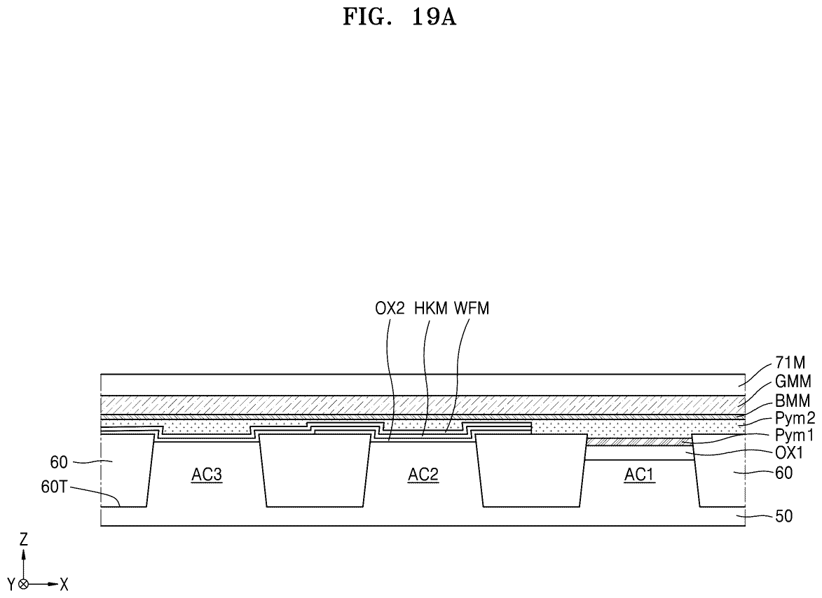

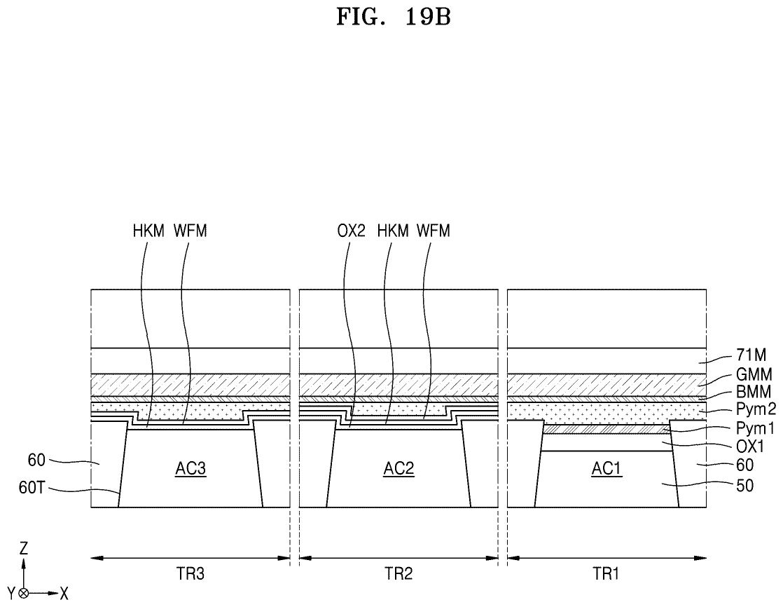

Referring to FIGS. 19A and 19B, in a result of FIGS. 18A and 18B, the fourth photoresist pattern PR4 may be removed from an upper surface of the work function metal material layer WFM on the second active region AC2 and the third active region AC3. Next, a second semiconductor material layer Pym2, a first metal material layer BMM, a second metal material layer GMM, and a capping material layer 71M may be sequentially formed on and the first semiconductor material layer Pym1 and the work function metal material layer WFM on the second active region AC2 and the third active region AC3.

The second semiconductor material layer Pym2 may include a material that is the same as or substantially similar to a material forming the second semiconductor layer Py2 included in the first, second, and third gate electrodes GE1, GE2, and GE3 of the first, second, and third transistors TR1, TR2, and TR3 described with reference to FIGS. 4 to 7. The first metal material layer BMM may include a material that is the same as or substantially similar to a material forming the first metal layer BM included in first, second, and third gate electrodes GE1, GE2, and GE3 of the first, second, and third transistors TR1, TR2, and TR3 described with reference to FIGS. 4 to 7. The second metal material layer GMM may include a material that is the same or substantially similar to a material forming the second metal layer GM included in first, second, and third gate electrodes GE1, GE2, and GE3 of the first, second, and third transistors TR1, TR2, and TR3 described with reference to FIGS. 4 to 7. The capping material layer 71M may include a material that is the same as or substantially similar to a material forming the gate capping layer 71 of the first, second, and third transistors TR1, TR2, and TR3 described with reference to FIGS. 4 to 7.

In some example embodiments, the second semiconductor material layer Pym2, the first metal material layer BMM, the second metal material layer GMM, and the capping material layer 71M may each be formed by an ALD process, a CVD process, a PECVD process, an LPCVD process, or so on.

The capping material layer 71M may be formed such that an upper surface of the capping material layer 71M may be at the same vertical level in each of the first active region AC1, the second active region AC2, and the third active region AC3.

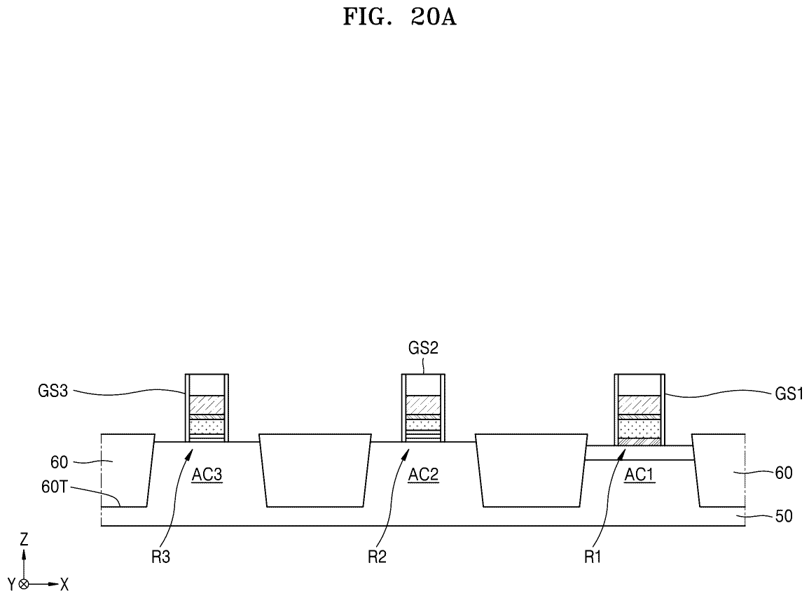

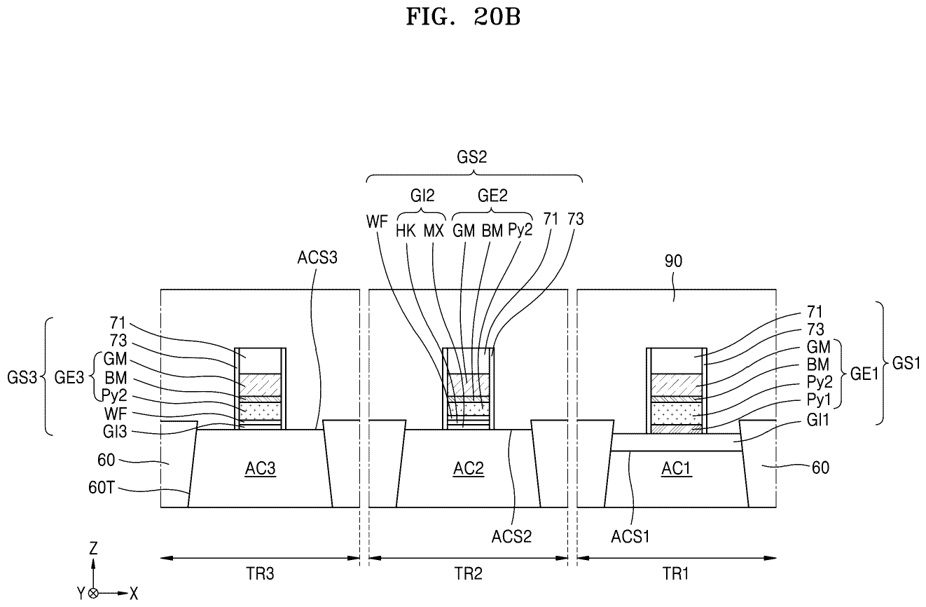

Referring to FIGS. 20A and 20B, in a result of FIGS. 19A and 19B, a second gate insulating layer GI2, a third gate insulating layer GI3, a first gate electrode GE1, a second gate electrode GE2, a third gate electrode GE3, and a gate capping layer 71 may be formed by patterning the first semiconductor material layer Pym1, the second insulating material layer OX2, the high dielectric material layer HKM, the work function metal material layer WFM, the second semiconductor material layer Pym2, the first metal material layer BMM, the second metal material layer GMM, and the capping material layer 71M. In this case, the first insulating material layer OX1 may not be patterned to function as the first gate insulating layer GI1. Next, an insulating layer (not illustrated), which covers a side wall of each of the second gate insulating layer GI2, the third gate insulating layer GI3, the first gate electrode GE1, the second gate electrode GE2, the third gate electrode GE3, and the gate capping layer 71, may be formed, and a gate spacer 73 may be formed by performing an anisotropic etch process on the insulating layer.

By performing the above-described process, a first gate structure GS1 may be formed on the first active region AC1, a second gate structure GS2 may be formed on the second active region AC2, and a third gate structure GS3 may be formed on the third active region AC3.

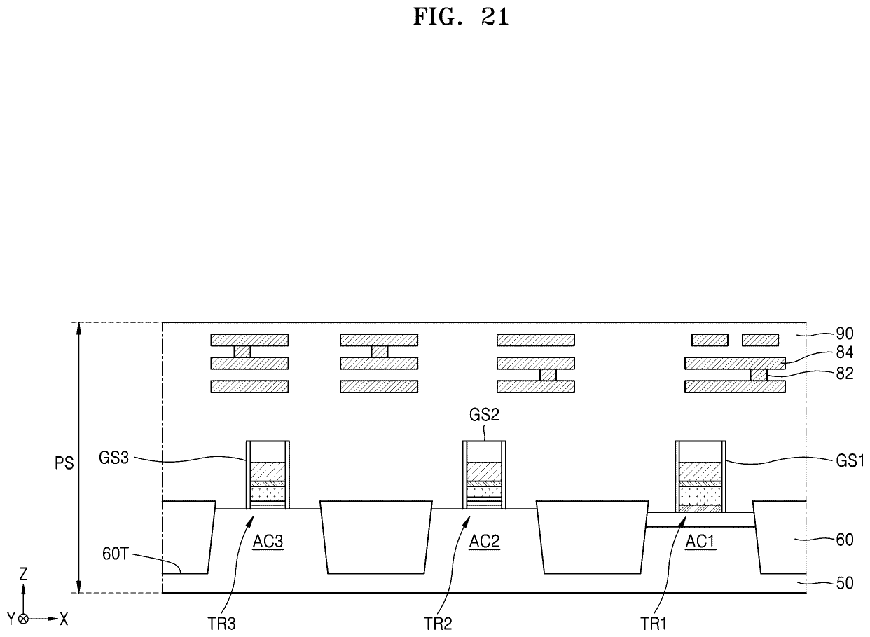

Referring to FIG. 21, a peripheral circuit wiring structure 80 and an interlayer insulating layer 90 that are electrically connected to the first, second, and third gate structures GS1, GS2, and GS3 and the first, second, and third active regions AC1, AC2, and AC3, may be formed.

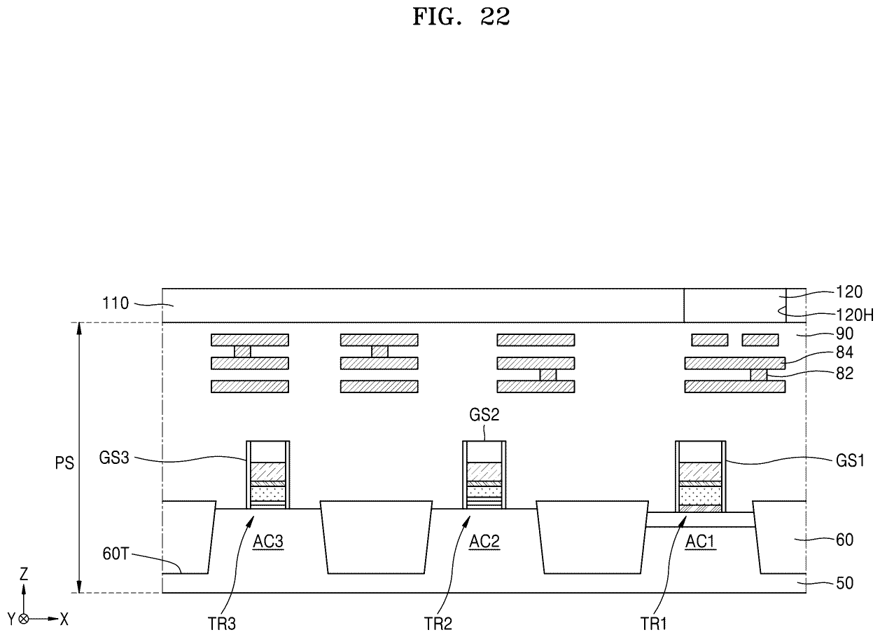

Referring to FIG. 22, a common source plate 110 may be formed on the interlayer insulating layer 90. Next, a mask pattern (not illustrated) may be formed on the common source plate 110, and an opening 120H may be formed by removing a part of the common source plate 110 by using the mask pattern as an etch mask. Next, an insulating layer (not illustrated) may be formed on the common source plate 110 to fill the opening 120H, and an insulating plug 120 may be formed by planarizing an upper portion of the insulating layer until an upper surface of the common source plate 110 is exposed.

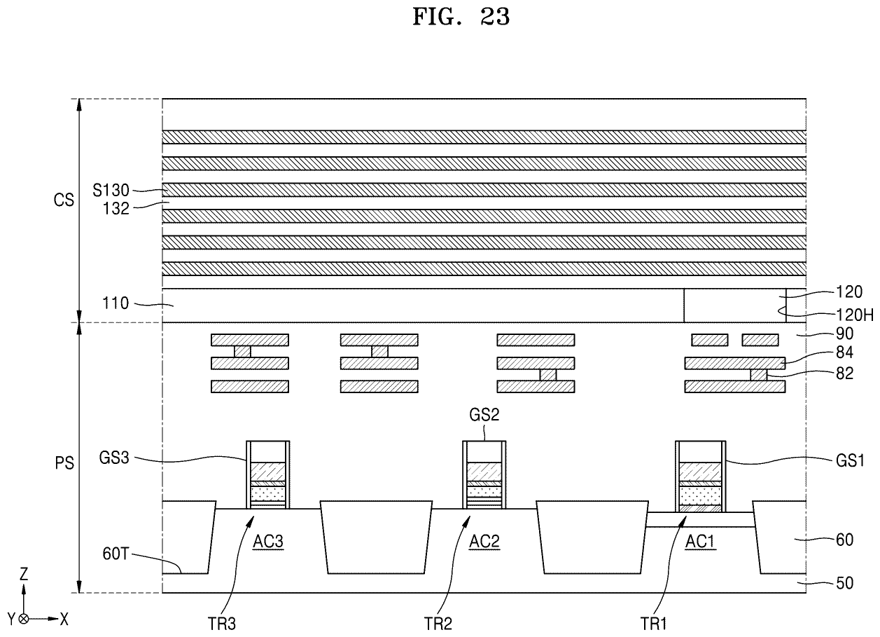

Referring to FIG. 23, a plurality of insulating layers 132 and a plurality of sacrificial layers S130 may be alternately formed on the common source plate 110. In some example embodiments, the plurality of insulating layers 132 may each include an insulating material, such as silicon oxide or silicon oxynitride, and the plurality of sacrificial layers S130 may each include silicon nitride, silicon oxynitride, or polysilicon doped with impurities, or so on.

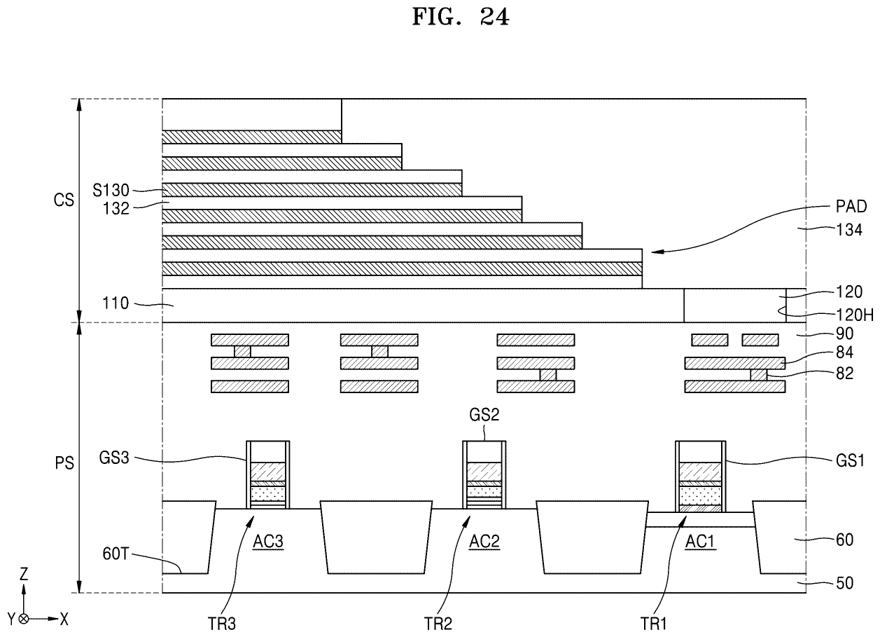

Referring to FIG. 24, a pad structure PAD may be formed by sequentially patterning the plurality of insulating layers 132 and the plurality of sacrificial layers S130. In some example embodiments, the pad structure PAD may be formed to have a step shape having a difference in upper surface level in a first horizontal direction (the X direction) (see FIG. 4). Next, a cover insulating layer 134, which covers the pad structure PAD, may be formed.

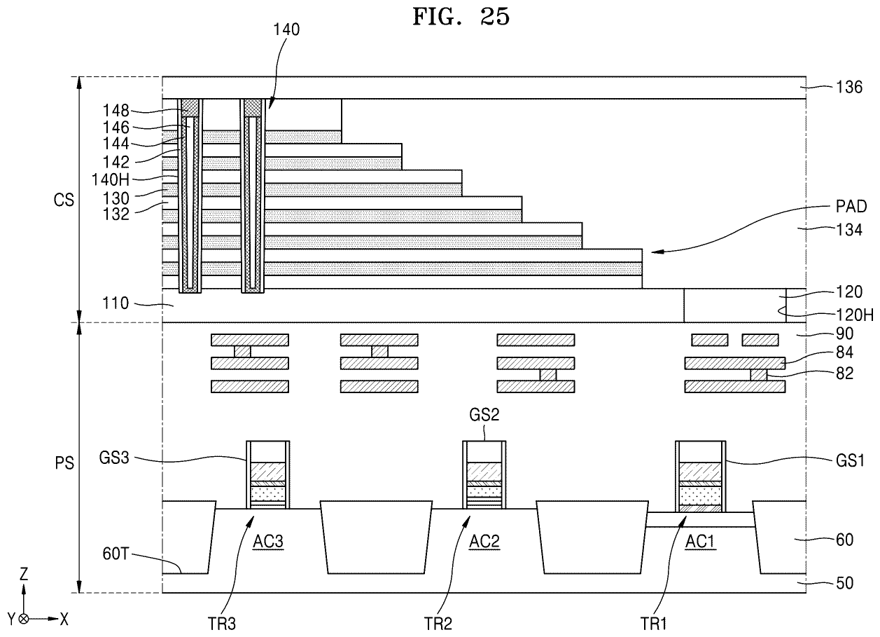

Referring to FIG. 25, a mask pattern (not illustrated) may be formed on the plurality of insulating layers 132 and the cover insulating layer 134, and a channel hole 140H may be formed by patterning the plurality of insulating layers 132 and the plurality of sacrificial layers S130 by using the mask pattern as an etch mask. Next, a channel structure 140 including a gate insulating layer 142, a channel layer 144, a buried insulating layer 146, and a conductive plug 148 may be formed on an inner wall of a channel hole 140H.

Although not illustrated in FIG. 25, during a process of forming the channel structure 140, a dummy channel structure (not illustrated) passing through the pad structure PAD may also be formed.

Next, an upper insulating layer 136, which covers the uppermost one of the plurality of insulating layers 132, the cover insulating layer 134, and the channel structure 140, may be formed.

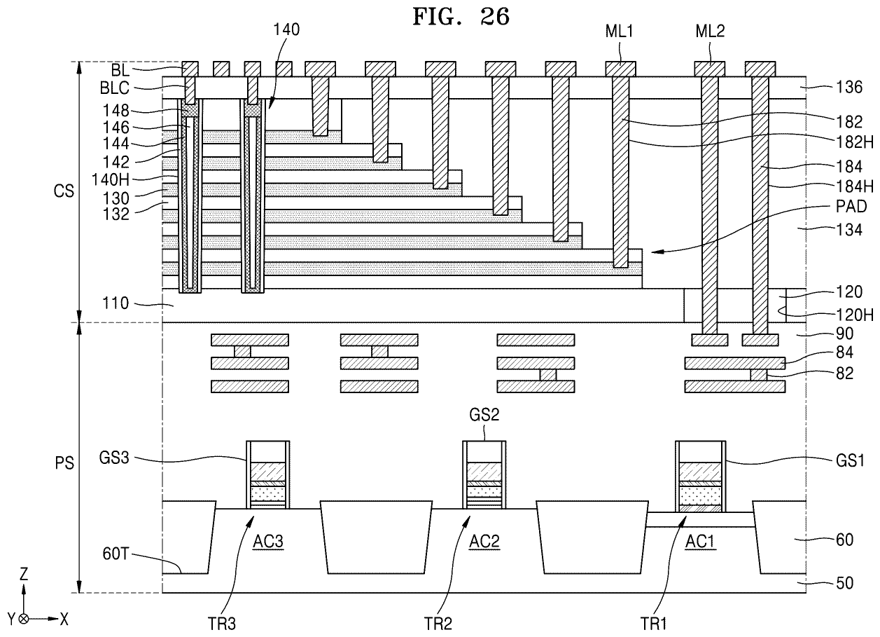

Referring to FIG. 26, a mask pattern (not illustrated) may be formed on the upper insulating layer 136, and a gate stack isolation opening (not illustrated) may be formed by removing parts of the plurality of insulating layers 132 and the plurality of sacrificial layers S130 by using the mask pattern as an etch mask. Next, the plurality of sacrificial layers S130 exposed by the inner wall of the gate stack isolation opening may be removed. In some example embodiments, a process of removing the plurality of sacrificial layers S130 may be a wet etching process using a phosphoric acid solution as an etchant. By removing the plurality of sacrificial layers S130, a part of a sidewall of the channel structure 140 may be exposed.

Next, a plurality of gate lines 130 may be formed in a space where the plurality of sacrificial layers S130 are removed. Thereafter, the inside of the gate stack isolation opening may be filled with an insulating material.

Next, a bit line contact BLC passing through the upper insulating layer 136 may be formed. Also, a cell contact hole 182H may be formed to pass through the upper insulating layer 136 and the cover insulating layer 134, and a cell contact 182 may be formed in the cell contact hole 182H. Also, a conductive through-via 184 may be formed in a through-hole 184H penetrating the upper insulating layer 136, the cover insulating layer 134, and the insulating plug 120.

Next, a bit line BL connected to the bit line contact BLC may be formed on the upper insulating layer 136, a first wiring line ML1 connected to the cell contact 182 and a second wiring line ML2 connected to the conductive through via 184 may be formed, and thereby, the semiconductor device 100 illustrated in FIGS. 4 to 7 may be manufactured.

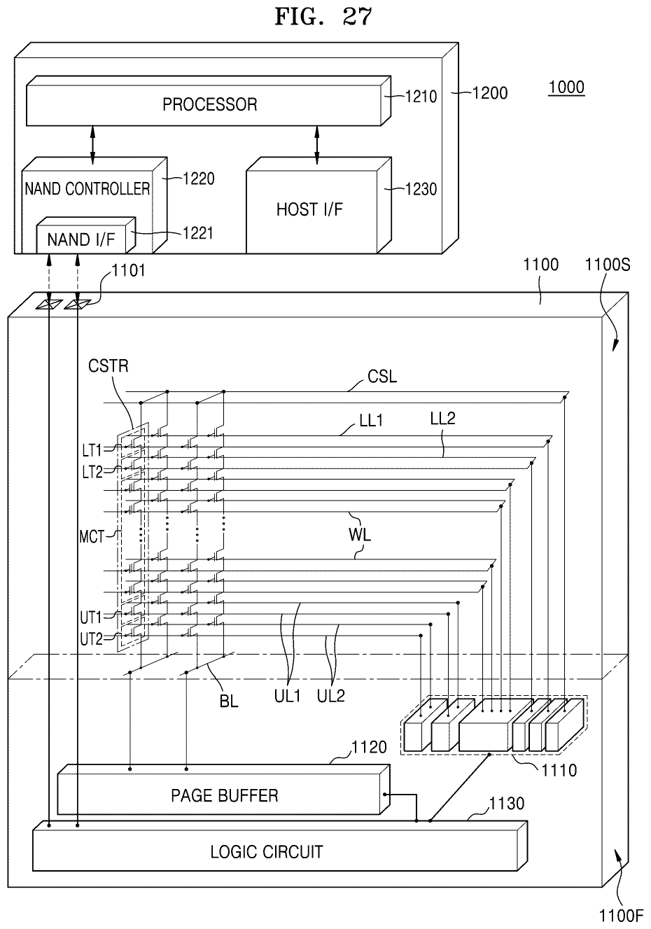

FIG. 27 is a diagram schematically illustrating an electronic system including a semiconductor device, according to an example embodiment.

Referring to FIG. 27, an electronic system 1000 according to an example embodiment may include a semiconductor device 1100 and a controller 1200 electrically connected to the semiconductor device 1100. The electronic system 1000 may be a storage device including one or a plurality of semiconductor devices 1100, or an electronic device including the storage device. For example, the electronic system 1000 may be a solid state drive (SSD) device, a Universal Serial Bus (USB), a computing system, a medical device, or a communication device including at least one semiconductor device 1100.

The semiconductor device 1100 may be a nonvolatile memory device. For example, the semiconductor device 1100 may be a NAND flash memory device including at least one of the structures described above for the semiconductor devices 100 and 200 with reference to FIGS. 4 to 8. The semiconductor device 1100 may include a first structure 1100F and a second structure 1100S on the first structure 1100F. In some example embodiments, the first structure 1100F may also be on a side of the second structure 1100S. The first structure 1100F may be a peripheral circuit structure including a decoder circuit 1110, a page buffer 1120, and a logic circuit 1130. The second structure 1100S may be a memory cell structure including a plurality of bit lines BL, a common source line CSL, a plurality of word lines WL, first and second gate upper lines UL1 and UL2, and first and second gate lower lines LL1 and LL2, and a plurality of memory cell strings CSTR between the plurality of bit lines BL and the common source line CSL.

In the second structure 1100S, the plurality of memory cell strings CSTR may each include the first and second lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may change depending on example embodiments.

In some example embodiments, the upper transistors UT1 and UT2 may include a string select transistor, and the lower transistors LT1 and LT2 may include a ground select transistor. The first and second gate lower lines LL1 and LL2 may be gate electrodes of the lower transistors LT1 and LT2, respectively. The plurality of word lines WL may be gate electrodes of the plurality of memory cell transistors MCT, respectively, and the first and second upper gate lines UL1 and UL2 may be gate electrodes of the upper transistors UT1 and UT2, respectively.

The common source line CSL, the first and second gate lower lines LL1 and LL2, the plurality of word lines WL, and the first and second gate upper lines UL1 and UL2 may be electrically connected to the decoder circuit 1110 through a plurality of first connection wires extending from the first structure 1100F to the second structure 1100S. The plurality of bit lines BL may be electrically connected to the page buffer 1120 through a plurality of second connection wires extending from the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and page buffer 1120 may be controlled by the logic circuit 1130.

The semiconductor device 1100 may communicate with the controller 1200 through input/output pads 1101 electrically connected to the logic circuit 1130. The input/output pads 1101 may be electrically connected to the logic circuit 1130 through input/output connection wires extending from the first structure 1100F to the second structure 1100S.

The controller 1200 may include a processor 1210, a NAND controller 1220, and a host interface 1230. Depending on example embodiments, the electronic system 1000 may include a plurality of semiconductor devices 1100, and in this case, the controller 1200 may control the plurality of semiconductor devices 1100.

The processor 1210 may control all operations of the electronic system 1000 including the controller 1200. The processor 1210 may operate according to preset firmware and may control the NAND controller 1220 to access the semiconductor device 1100. The NAND controller 1220 may include a NAND interface 1221 that processes communication with the semiconductor device 1100. Through the NAND interface 1221, a control command for controlling the semiconductor device 1100, data to be stored in the plurality of memory cell transistors MCT of the semiconductor device 1100, data to be read from the plurality of memory cell transistors MCT of the semiconductor device 1100, and so on may be transmitted. The host interface 1230 may provide a communication function between the electronic system 1000 and an external host. When receiving a control command from an external host through the host interface 1230, the processor 1210 may control the semiconductor device 1100 in response to the control command.

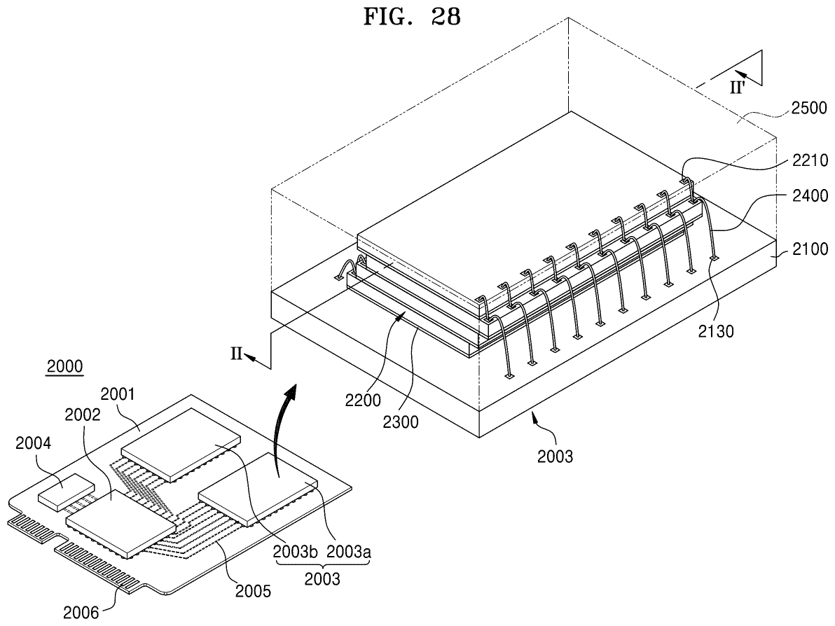

FIG. 28 is a perspective view schematically illustrating an electronic system including a semiconductor device, according to an example embodiment.

Referring to FIG. 28, an electronic system 2000 according to an example embodiment may include a main board 2001, a controller 2002 mounted on the main board 2001, one or more semiconductor packages 2003, and dynamic random access memory (DRAM) 2004. The semiconductor package 2003 and the DRAM 2004 may be connected to the controller 2002 through a plurality of wiring patterns 2005 formed on the main board 2001.

The main board 2001 may include a connector 2006 including a plurality of pins coupled to an external host. The number and arrangement of the plurality of pins included in the connector 2006 may change depending on communication interfaces between the electronic system 2000 and an external host. In some example embodiments, the electronic system 2000 may communicate with an external host according to any one of interfaces, such as USB, peripheral component interconnect express (PCI-Express), serial advanced technology attachment (SATA), and M-Phy for universal flash storage (UFS). In some example embodiments, the electronic system 2000 may operate with power supplied from an external host through the connector 2006. The electronic system 2000 may further include a power management integrated circuit (PMIC) that distributes the power supplied from the external host to the controller 2002 and the semiconductor package 2003.

The controller 2002 may write data to the semiconductor package 2003 or read data from the semiconductor package 2003, and may increase an operating speed of the electronic system 2000.

The DRAM 2004 may be a buffer memory for reducing a speed difference between the semiconductor package 2003, which is a data storage space, and an external host. The DRAM 2004 included in the electronic system 2000 may operate as a type of cache memory and may also provide a space for temporarily storing data during a control operation for the semiconductor package 2003. When the electronic system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b separated from each other. The first and second semiconductor packages 2003a and 2003b may each include a plurality of semiconductor chips 2200. The first and second semiconductor packages 2003a and 2003b may each include a package substrate 2100, the plurality of semiconductor chips 2200 on the package substrate 2100, an adhesive layer 2300 on a lower surface of each of the plurality of semiconductor chips 2200, a connection structure 2400 that electrically connects the plurality of semiconductor chips 2200 to the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. The plurality of semiconductor chips 2200 may each include input/output pads 2210. The input/output pads 2210 may correspond to the input/output pads 1101 of FIG. 27. Each of the plurality of semiconductor chips 2200 may include a plurality of gate stacks and a plurality of channel structures. The plurality of semiconductor chips 2200 may each include at least one structure among the structures described above for the semiconductor devices 100 and 200 with reference to FIGS. 4 to 8.

In some example embodiments, the connection structure 2400 may include bonding wires that respectively electrically connect the input/output pads 2210 to package top pads 2130. Accordingly, in the first and second semiconductor packages 2003a and 2003b, the plurality of semiconductor chips 2200 may be electrically connected to each other by a bonding wire method and may be electrically connected to the package upper pads 2130 of the package substrate 2100. In some example embodiments, in the first and second semiconductor packages 2003a and 2003b, the plurality of semiconductor chips 2200 may also be electrically connected to each other by a connection structure including through-electrodes (through silicon via (TSV)) instead of the connection structure 2400 of a bonding wire method.

In some example embodiments, the controller 2002 and the plurality of semiconductor chips 2200 may be included in one package. In some example embodiments, the controller 2002 and the plurality of semiconductor chips 2200 may be mounted on a separate interposer substrate different from the main board 2001, and the controller 2002 may also be connected to the plurality of semiconductor chips 2200 through wires formed on the interposer substrate.

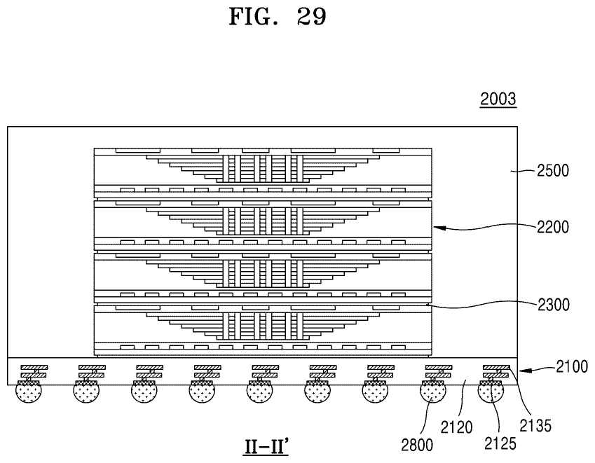

FIG. 29 is a cross-sectional view schematically illustrating semiconductor packages according to an example embodiment. FIG. 29 illustrates in more detail a configuration taken along line II-II′ of FIG. 28.

Referring to FIG. 29, the package substrate 2100 of the semiconductor package 2003 may be a printed circuit board. The package substrate 2100 may include a package substrate body 2120, the plurality of package upper pads 2130 (see FIG. 28) arranged on an upper surface of the package substrate body 2120, a plurality of lower pads 2125 arranged on or exposed through a lower surface of the package substrate body 2120, and a plurality of internal wires 2135 electrically connecting the plurality of upper pads 2130 to the plurality of lower pads 2125 inside the package substrate body 2120. The plurality of upper pads 2130 may be electrically connected to the plurality of connection structures 2400 (see FIG. 28). The plurality of lower pads 2125 may be connected to the plurality of wiring patterns 2005 on the main board 2001 of the electronic system 2000 illustrated in FIG. 28 through a plurality of conductive connectors 2800.

The plurality of semiconductor chips 2200 may each include a semiconductor substrate and a first structure and a second structure sequentially stacked on the semiconductor substrate. The first structure may include a peripheral circuit region including a plurality of peripheral wires. The second structure may include a common source line, a gate stack on the common source line, a channel structure passing through the gate stack, a plurality of bit lines electrically connected to the channel structure, and gate connection wires electrically connected to the plurality of word lines (WL in FIG. 27) included in the gate stack through contacts. In some example embodiments, the plurality of semiconductor chips 2200 may each include at least one structure among the structures described above for the semiconductor devices 100 and 200 with reference to FIGS. 4 to 8.

The plurality of semiconductor chips 2200 may each include through-wires electrically connected to the plurality of peripheral wires of the first structure and extending into the second structure. The through-wires may be arranged outside the gate stack. In some example embodiments, the semiconductor package 2003 may further include through-wires passing through the gate stack. The plurality of semiconductor chips 2200 may each further include input/output pads (2210 in FIG. 28) electrically connected to the plurality of peripheral wires of the first structure.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

As described above, some example embodiments are disclosed in the drawings and specification. Although the example embodiments are described in the inventive concepts by using certain terms, this is used only for the purpose of describing the technical idea of the inventive concepts and is not used to limit the meaning or scope of the inventive concepts as set forth in the claims. Therefore, those skilled in the art will understand that various modifications and other equivalent example embodiments may be derived therefrom. Therefore, the true technical protection scope of the inventive concepts should be determined by the technical idea of the attached patent claims.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a substrate including a first active region, a second active region, and a third active region defined by a device isolation layer;
a first transistor on the first active region, the first active region including a first gate structure, the first gate structure including a first gate insulating layer on the first active region and a first gate electrode on the first gate insulating layer;
a second transistor on the second active region, the second active region including a second gate structure, the second gate structure including a second gate insulating layer on the second active region, a work function metal layer on the second gate insulating layer, and a second gate electrode on the work function metal layer, the second gate insulating layer including a high dielectric layer, the second gate electrode including metal; and
a third transistor on the third active region, the third active region including a third gate structure, the third gate structure including a third gate insulating layer on the third active region, a work function metal layer on the third gate insulating layer, and a third gate electrode on the work function metal layer, the third gate insulating layer including a high dielectric layer, a third gate electrode including metal,
wherein the first gate electrode includes a first semiconductor layer and a second semiconductor layer that are sequentially on the first gate insulating layer and each include polysilicon.

2. The semiconductor device of claim 1, wherein an upper surface of the first gate structure is at a same vertical level as an upper surface of the second gate structure and an upper surface of the third gate structure.

3. The semiconductor device of claim 1, wherein an upper surface of the first gate insulating layer is at a lower vertical level than an upper surface of the second active region and an upper surface of the third active region.

4. The semiconductor device of claim 1, wherein the second gate insulating layer includes a first insulating layer on the second active region and a second insulating layer on the first insulating layer, the first insulating layer including silicon oxide, the second insulating layer including a high dielectric layer.

5. The semiconductor device of claim 4, wherein an upper surface of the first semiconductor layer is at a same vertical level as an upper surface of the first insulating layer.

6. The semiconductor device of claim 1, wherein an upper surface of the first semiconductor layer is at a same vertical level as an upper surface of the third gate insulating layer.

7. The semiconductor device of claim 1, wherein a thickness of the first gate insulating layer is greater than a thickness of the second gate insulating layer, and the thickness of the second gate insulating layer is greater than a thickness of the third gate insulating layer.

8. The semiconductor device of claim 1, wherein the first transistor has a first threshold voltage, the second transistor has a second threshold voltage that is lower than the first threshold voltage, and the third transistor has a third threshold voltage that is lower than the second threshold voltage.

9. A semiconductor device comprising:
a peripheral circuit structure on a substrate; and
a cell array structure on the peripheral circuit structure, the cell array structure including a plurality of memory cells provided in a vertical direction perpendicular to an upper surface of the substrate,
wherein the peripheral circuit structure comprises,
a device isolation layer on the substrate and defining a first active region, a second active region, and a third active region,
a first gate structure on the first active region, the first gate structure including a first gate insulating layer and a first gate electrode on the first gate insulating layer,
a second gate structure on the second active region, the second gate structure including a second gate insulating layer, a work function metal layer on the second gate insulating layer, and a second gate electrode on the work function metal layer, a second gate insulating layer including a high dielectric layer, the second gate electrode including metal, and
a third gate structure on the third active region, the third gate structure including a third gate insulating layer, a work function metal layer on the third gate insulating layer, and a third gate electrode on the work function metal layer, the third gate insulating layer including a high dielectric layer, a third gate electrode including metal, and
wherein the first gate electrode includes a first semiconductor layer and a second semiconductor layer that are sequentially on the first gate insulating layer and each include polysilicon.

10. The semiconductor device of claim 9, wherein the cell array structure comprises:
a common source plate on the peripheral circuit structure;
a plurality of gate electrodes on the common source plate and separated from each other in the vertical direction; and
a channel structure extending in the vertical direction from an upper surface of the common source plate by passing through the plurality of gate electrodes.

11. The semiconductor device of claim 9, wherein
the cell array structure further includes a plurality of first bonding pads,
the peripheral circuit structure further includes a plurality of second bonding pads, and
the first bonding pads are bonded to corresponding ones of the second bonding pads, respectively.

12. The semiconductor device of claim 9, wherein an upper surface of the first gate structure is at a same vertical level as an upper surface of the second gate structure and an upper surface of the third gate structure.

13. The semiconductor device of claim 9, wherein an upper surface of the first gate insulating layer is at a lower vertical level than an upper surface of the second active region and an upper surface of the third active region.

14. The semiconductor device of claim 13, wherein
the second gate insulating layer includes a first insulating layer on the second active region and including silicon oxide, and a second insulating layer on the first insulating layer, the first insulating layer including silicon oxide, the second insulating layer including a high dielectric layer, and
an upper surface of the first semiconductor layer is at a same vertical level as an upper surface of the first insulating layer.

15. The semiconductor device of claim 9, wherein an upper surface of the first semiconductor layer is at a same vertical level as an upper surface of the third gate insulating layer.

16. The semiconductor device of claim 9, wherein a thickness of the first gate insulating layer is greater than a thickness of the second gate insulating layer, and the thickness of the second gate insulating layer is greater than a thickness of the third gate insulating layer.

17. The semiconductor device of claim 9, wherein the first active region and the first gate structure constitute a first transistor having a first threshold voltage, the second active region and the second gate structure constitute a second transistor having a second threshold voltage that is lower than the first threshold voltage, and the third active region and the third gate structure constitute a third transistor having a third threshold voltage that is lower than the second threshold voltage.

18. An electronic system comprising:
a main board;
a semiconductor device on the main board; and
a controller electrically connected to the semiconductor device on the main board,
wherein the semiconductor device comprises,
a peripheral circuit structure on a substrate, and
a cell array structure on the peripheral circuit structure, the cell array structure including a plurality of memory cells provided in a vertical direction perpendicular to an upper surface of the substrate,
wherein the peripheral circuit structure comprises,
a device isolation layer on the substrate and defining a first active region, a second active region, and a third active region,
a first gate structure on the first active region, the first gate structure including a first gate insulating layer and a first gate electrode on the first gate insulating layer, the first gate insulating layer including a silicon oxide film,
a second gate structure on the second active region, the second gate structure including a second gate insulating layer, a work function metal layer on the second gate insulating layer, and a second gate electrode on the work function metal layer, the second gate insulating layer including a first insulating layer and a second insulating layer, the first insulating layer including a silicon oxide film, the second insulating layer including a high dielectric film, the second gate electrode including metal, and
a third gate structure on the third active region, the third gate structure including a third gate insulating layer, a work function metal layer on the third gate insulating layer, and a third gate electrode on the work function metal layer, the third gate insulating layer including a high dielectric layer, the third gate electrode including metal,
wherein the first gate electrode includes a first semiconductor layer and a second semiconductor layer that are sequentially on the first gate insulating layer and each include polysilicon, and
wherein an upper surface of the first semiconductor layer is at a same vertical level as an upper surface of the first insulating layer and an upper surface of the third gate insulating layer.

19. The electronic system of claim 18, wherein an upper surface of the first gate structure is at a same vertical level as an upper surface of the second gate structure and an upper surface of the third gate structure.

20. The electronic system of claim 18, wherein the first active region and the first gate structure constitute a first transistor having a first threshold voltage, the second active region and the second gate structure constitute a second transistor having a second threshold voltage that is lower than the first threshold voltage, and the third active region and the third gate structure constitute a third transistor having a third threshold voltage that is lower than the second threshold voltage.
